(19) United States
(12) Patent Application Publication
(10) Pub. No.: US 2024/0349967 A1
(43) Pub. Date: Oct. 24, 2024

(54) VACUUM CLEANER FOR DETECTING MOISTURE INGRESS

(71) Applicant: SAMSUNG ELECTRONICS CO., LTD., Suwon-si (KR)

(72) Inventors: Seongu LEE, Suwon-si (KR); Yongdae LEE, Suwon-si (KR); Seungmoo LIM, Suwon-si (KR); Jaeshik JEONG, Suwon-si (KR)

(21) Appl. No.: 18/611,710

(22) Filed: Mar. 21, 2024

Related U.S. Application Data
(63) Continuation of application No. PCT/KR24/95321, filed on Feb. 16, 2024.

(30) Foreign Application Priority Data
Apr. 21, 2023 (KR) 10-2023-0052948
Jun. 26, 2023 (KR) 10-2023-0082186

(51) Int. Cl. A47L 9/28

(52) U.S. Cl. CPC A47L 9/2889; A47L 9/2805; A47L 9/2842; A47L 9/2857; A47L 9/2884

(57) ABSTRACT

A vacuum cleaner includes a battery module configured to supply power to a cleaner body, a motor assembly including a printed circuit board (PCB), a suction motor, and an impeller arranged in this order along a direction of a flow path in the cleaner body, a moisture detection circuit provided on the PCB of the motor assembly and configured to detect moisture introduced through the flow path, and at least one processor configured to, when it is determined, through the moisture detection circuit, that moisture has been introduced into the cleaner body, stop driving of the suction motor.

### BACKGROUND

### 1. Field

Embodiments of the disclosure relate to a vacuum cleaner for detecting moisture (liquid) introduced into a cleaner body.

### 2. Description of the Related Art

A cordless vacuum cleaner is a type of electrically powered cleaner that is used by charging a battery included in the vacuum cleaner itself without having to connect a line to an outlet. The cordless vacuum cleaner includes a suction motor that generates suction power, and thus, may suck up foreign materials, such as dust, together with air, from a cleaner head or attachment (e.g., a brush) through the suction power generated by the suction motor, and collect the sucked-up foreign materials by separating the sucked-up foreign materials from the air.

When the cordless vacuum cleaner sucks up foreign materials along with air from the cleaner head, a liquid may be sucked up in a case where when there is a liquid on a surface to be cleaned. When the liquid is introduced into the cordless vacuum cleaner, the introduced liquid may cause the cordless vacuum cleaner to malfunction. For example, circuit components in the cordless vacuum cleaner may be burned out by the liquid.

### SUMMARY

A vacuum cleaner according to an embodiment of the disclosure includes a battery module configured to supply power to a cleaner body, a motor assembly including a printed circuit board (PCB), a suction motor, and an impeller arranged in this order along a direction of a flow path in the cleaner body, a moisture detection circuit provided on the PCB of the motor assembly and configured to detect moisture introduced thereinto through the flow path, and at least one processor configured to, when it is determined, through the moisture detection circuit, that moisture is introduced into the cleaner body, stop driving of the suction motor.

### BRIEF DESCRIPTION OF THE DRAWINGS

FIG. 1 is a view for describing a vacuum cleaner for detecting moisture, according to an embodiment of the disclosure.

FIG. 2 is a block diagram for describing a function of a cleaner body, according to an embodiment of the disclosure.

FIG. 3 is a view for describing operations of processors of a vacuum cleaner, according to an embodiment of the disclosure.

FIG. 4 is a view for describing a moisture ingress path, according to an embodiment of the disclosure.

FIG. 5A is a view for describing a position of a moisture detection circuit, according to an embodiment of the disclosure.

FIG. 5B is a view for describing a position of a moisture detection circuit, according to an embodiment of the disclosure.

FIG. 6 is a flowchart for describing a method of controlling driving of a suction motor based on moisture ingress, according to an embodiment of the disclosure.

FIG. 7 is a view for describing a moisture detection circuit, according to an embodiment of the disclosure.

FIG. 8 is a diagram for describing an electrical conductivity of a solution, according to an embodiment of the disclosure.

FIG. 9 is a diagram for describing a correlation between an electrical conductivity of a solution and a resistance value, according to an embodiment of the disclosure.

FIG. 10 is a view for describing an example of a moisture detection circuit, according to an embodiment of the disclosure.

FIG. 11 is a view for describing various types of moisture detection circuits, according to an embodiment of the disclosure.

FIG. 12 is a view for describing an operation in which a vacuum cleaner outputs a notification, according to an embodiment of the disclosure.

FIG. 13 is a flowchart for describing a method of determining the amount of moisture introduced into a cleaner body, according to an embodiment of the disclosure.

FIG. 14 is a view for describing a plurality of moisture detection circuits, according to an embodiment of the disclosure.

FIG. 15 is a flowchart for describing a method of detecting moisture ingress before driving of a suction motor, according to an embodiment of the disclosure.

FIG. 16 is a diagram for describing reference voltage values, according to an embodiment of the disclosure.

FIG. 17 is a flowchart for describing a method of detecting moisture ingress during driving of a suction motor, according to an embodiment of the disclosure.

FIG. 18 is a flowchart for describing a method of detecting moisture ingress in a maximum suction power mode, according to an embodiment of the disclosure.

FIG. 19 is a diagram for describing an operation mode of a vacuum cleaner, according to an embodiment of the disclosure.

FIG. 20 is a flowchart for describing a method of changing a suction power mode according to moisture ingress, according to an embodiment of the disclosure.

FIG. 21 is a view for describing a cleaning system, according to an embodiment of the disclosure.

FIG. 22 is a view illustrating an example of a graphical user interface (GUI) for setting a moisture detection sensitivity, according to an embodiment of the disclosure.

FIG. 23 is a view for describing an operation in which a user terminal outputs a notification, according to an embodiment of the disclosure.

### DETAILED DESCRIPTION

The terms used herein will be briefly described, and embodiments of the disclosure will be described in detail.

The terms used herein are those general terms currently widely used in the art in consideration of functions in an embodiment of the disclosure but the terms may vary according to the intention of one of ordinary skill in the art, precedents, or new technology in the art. Also, some of the terms used herein may be arbitrarily chosen by the present applicant, and in this case, these terms are defined in detail in the description of an embodiment of the disclosure below. Accordingly, the specific terms used herein should be defined based on the unique meanings thereof and the whole context of the disclosure.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. Throughout the disclosure, the expression “at least one of a, b or c” or “at least one selected from a, b and c” indicates only a, only b, only c, both a and b, both a and c, both b and c, all of a, b, and c, or variations thereof.

When a part “includes” or “comprises” an element throughout the disclosure, unless there is a particular description contrary thereto, the part may further include other elements, not excluding the other elements. Also, the term such as “ . . . unit” or “ . . . module” used herein refers to a unit that performs at least one function or operation, and the unit may be implemented as hardware or software or as a combination of hardware and software.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Embodiments of the disclosure will now be described more fully with reference to the accompanying drawings for one of ordinary skill in the art to be able to perform the embodiment of the disclosure without any difficulty. However, an embodiment of the disclosure may be implemented in various different forms and is not limited to the embodiment described herein. Also, in the drawings, parts irrelevant to the description are omitted in order to clearly describe an embodiment of the disclosure, and like reference numerals denote like elements throughout the disclosure.

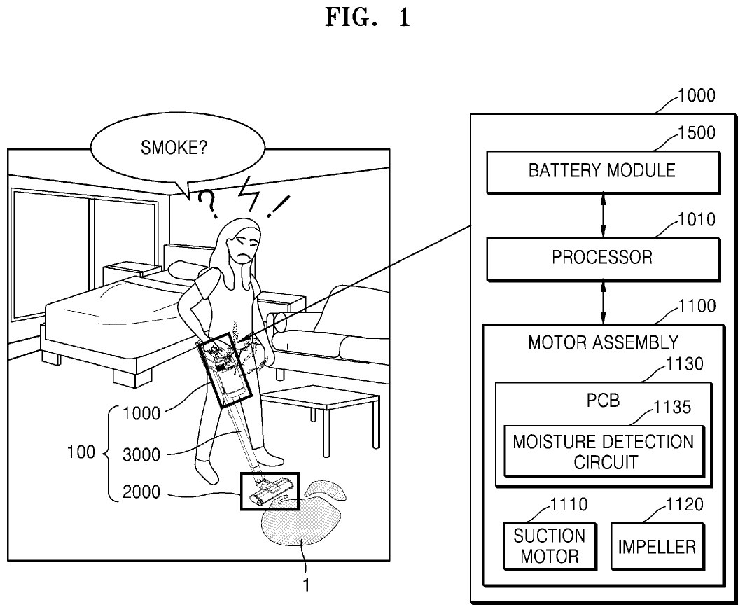

FIG. 1 is a view for describing a vacuum cleaner for detecting moisture, according to an embodiment of the disclosure.

Although a cordless vacuum cleaner 100 is described as an example in FIG. 1, the disclosure is not limited thereto. For example, an embodiment of the disclosure may be applied to a robot vacuum cleaner.

The cordless vacuum cleaner 100 may refer to a vacuum cleaner that has a rechargeable battery therein and does not require a power cord to be connected to an outlet during cleaning. The cordless vacuum cleaner 100 according to an embodiment of the disclosure may be a stick-type cleaner including a cleaner body 1000, a brush device 2000, and an extension pipe 3000. However, not all of the components shown in FIG. 1 are essential components. The cordless vacuum cleaner 100 may include more or fewer components than those illustrated in FIG. 1. For example, the cordless vacuum cleaner 100 may include the cleaner body 1000 and the brush device 2000 without the extension pipe 3000. Also, the cordless vacuum cleaner 100 may further include a station (not shown) for discharging dust from the cleaner body 1000 and charging the battery.

The cleaner body 1000 may include a suction motor 1110 configured to form a vacuum in the cordless vacuum cleaner 100, and a dust collection container (dust bin) in which foreign materials sucked up from a surface to be cleaned (e.g., a floor, bedding, or a sofa) are accommodated, and is a portion moved by being held a user during cleaning.

The cleaner body 1000 may include an extension pipe mounting portion on which the extension pipe 3000 is mounted. The extension pipe 3000 may be formed as a hollow pipe. According to an embodiment of the disclosure, the extension pipe 3000 has a certain rigidity. According to an embodiment of the disclosure, the extension pipe 3000 may be formed as a flexible hose. The brush device 2000 may be detachably connected to one end of the extension pipe 3000. The other end of the extension pipe 3000 may be detachably connected to the extension pipe mounting portion of the cleaner body 1000. The extension pipe 3000 may be configured to transmit suction power generated through the suction motor 1110 of the cleaner body 1000 to the brush device 2000, and move air and foreign materials sucked up through the brush device 2000 to the cleaner body 1000. The extension pipe 3000 may be formed or provided in multiple stages between the cleaner body 1000 and the brush device 2000. There may be two or more extension pipes 3000.

The brush device 2000 connected to the cleaner body 1000 or the extension pipe 3000 is a device configured to suck up air and foreign materials of a surface to be cleaned by being pressed against the surface to be cleaned. The brush device 2000 may also be referred to as a cleaner head. The brush device 2000 may be rotatably coupled to the extension pipe 3000. The brush device 2000 may include, but is not limited to, a motor and a drum to which a rotating brush is attached. According to an embodiment of the disclosure, the brush device 2000 may further include at least one processor configured to control communication with the cleaner body 1000. A type of the brush device 2000 may vary. For example, the brush device 2000 may include, but is not limited to, a general brush (a hard floor brush), a carpet brush, a bedding brush, a pet brush, and a wet brush according to usage. Different types of brush devices 2000 may have different maximum motor outputs and may operate based on different electrical inputs corresponding to characteristics of applications.

According to an embodiment of the disclosure, each of the cleaner body 1000, the brush device 2000, and the extension pipe 3000 included in the cordless vacuum cleaner 100 may include power lines (e.g., a positive (+) power line and a negative (−) power line) and a signal line. The power lines may be lines for transmitting power supplied from a battery module 1500 to the cleaner body 1000 and the brush device 2000 connected to the cleaner body 1000. The signal line is different from the power lines, and may be a line for transmitting and receiving a signal between the cleaner body 1000 and the brush device 2000. The signal line may be implemented to be connected to the power lines in the brush device 2000.

Referring to FIG. 1, the cleaner body 1000 may include, but is not limited to, the battery module 1500 configured to supply power to the cleaner body 1000, at least one processor 1010, and a motor assembly 1100 configured to generate suction power. The motor assembly 1100 may include the suction motor 1110 and an impeller 1120 coupled to or mounted on a rotation shaft of the suction motor 1110. When the suction motor 1110 is driven and the impeller 1120 rotates, suction pressure is generated to suck up air and foreign materials on a surface to be cleaned through an intake flow path. The air is adiabatically compressed by the impeller 1120 to increase a temperature. In a case where the impeller 1120 is located on an upstream side of the suction motor 1110, the suction motor 1110 may be exposed to the high-temperature compressed air. In this case, a motor coil of the suction motor 1110 may be cooled by the sucked air, but when the high-temperature compressed air flows around the suction motor 1110, the motor coil may not be effectively cooled. Rather, the high-temperature compressed air may increase a temperature of the motor coil, and the output and efficiency of the suction motor 1110 may decrease.

The motor assembly 1100 according to an embodiment of the disclosure has an inverted motor structure in which the impeller 1120 is located on a downstream side of the suction motor 1110 based on an air flow direction. For example, in such an embodiment where the motor assembly 1100 has an inverted motor structure, a printed circuit board (PCB) 1130, the suction motor 1110, and the impeller 1120 may be arranged in this order along a direction of a flow path. According to an embodiment including the motor assembly 1100 having the inverted motor structure, low-temperature air before compression passes around the suction motor 1110. Accordingly, the low-temperature air may effectively cool the motor coil. Because the motor coil may be maintained at a stable operating temperature, the output and efficiency of the suction motor 1110 may be improved.

In an embodiment including the motor assembly 1100 having the inverted motor structure, because the PCB 1130 is located on an upstream side of the suction motor 1110 based on an air flow direction, when a liquid 1 of the surface to be cleaned is introduced into the cleaner body 1000, a probability that a circuit or a wiring (e.g., wire harness) included in the PCB 1130 is burned out by the liquid 1 may increase. For example, when the liquid 1 such as water is sucked into the cleaner body 1000 along with dust, due to the sucked liquid 1 (e.g., water, coffee, and dirt), insulation tracking may occur in a circuit (e.g., a suction motor controller circuit or a main circuit) or a wire harness connector inside the cleaner body 1000, leading to circuit component burnout, combustion, or fire. In the disclosure, examples of the liquid 1 may include a beverage (e.g., water, coffee, wine, or juice), dog urine, soup, salt water, etc., and may also include wet food, wet paper, etc. The liquid 1 may be a gel.

In order to prevent circuit burnout and insulation tracking when the liquid 1 is introduced, the entire PCB 1130 may be thickly coated. However, workability and productivity are reduced due to coating liquid application and drying operations for the thick coating on the entire PCB 1130, and when the coating liquid application operation is incorrect, it is likely to lead to poor quality. For example, when a coating liquid is applied to a connector contact point, a contact defect may occur. Also, because the weight of the cleaner body 1000 increases due to the coating liquid, product competitiveness may be lowered.

A guard device (e.g., a cap grille) may be applied to a front portion of the PCB 1130 to minimize the risk of introduction of the liquid 1. However, suction power loss (e.g., 2 to 5 W) occurs due to the application of the cap grille, and the cooling effect of a circuit element included in the PCB 1130 is also limited. Also, when a large amount of liquid 1 is introduced, the liquid 1 passes through the cap grille and reaches the front portion of the PCB 1130, causing insulation tracking, which may lead to circuit burnout and fire.

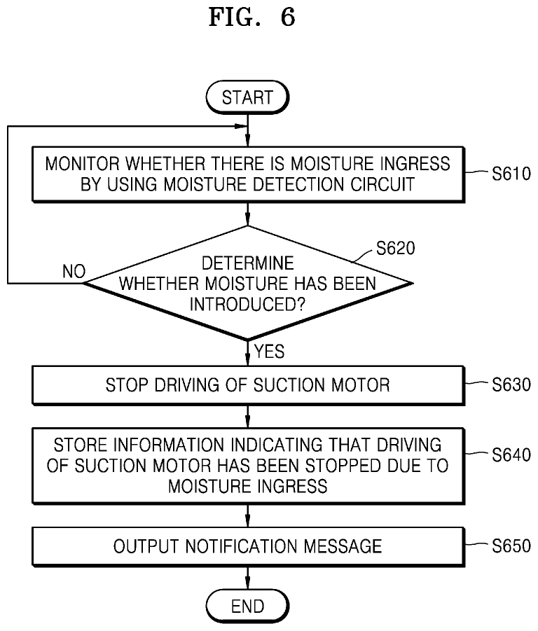

Accordingly, according to an embodiment of the disclosure, a moisture detection circuit 1135 is located on the PCB 1130 of the motor assembly 1100 in order to prevent circuit burnout and fire caused by insulation tracking, so that the cleaner body 1000 detects moisture (e.g., the liquid 1) introduced through the moisture detection circuit 1135 and stops driving of the suction motor 1110. A method of stopping driving of the suction motor 1110 when the cleaner body 1000 detects introduction of moisture (e.g., the liquid 1) through the moisture detection circuit 1135, will be described below in detail with reference to FIG. 6.

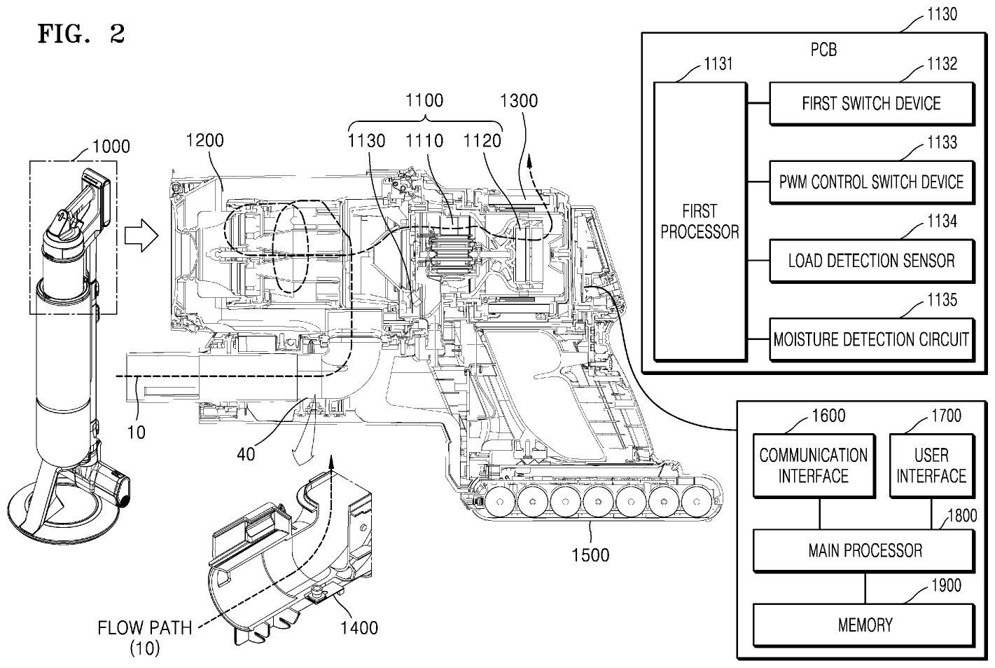

Hereinafter, a configuration of the cleaner body 1000 will be described in more detail with reference to FIG. 2.

FIG. 2 is a block diagram for describing a function of the cleaner body 1000, according to an embodiment of the disclosure.

Referring to FIG. 2, the cleaner body 1000 may include a suction power generating device (hereinafter, referred to as the motor assembly 1100) for generating suction power for sucking up foreign materials on a surface to be cleaned, a dust collection container 1200 (also referred to as a dust bin) in which the foreign materials sucked up from the surface to be cleaned are accommodated, a filter unit 1300, a pressure sensor 1400, the battery module 1500 for supplying power to the motor assembly 1100, a communication interface 1600, a user interface 1700, a main processor 1800, and a memory 1900. However, not all of the components shown in FIG. 2 are essential components. The cleaner body 1000 may include more or fewer components than those illustrated in FIG. 2. For example, the cleaner body 1000 may further include a motion sensor (not shown).

Hereinafter, each component will be described in detail.

The motor assembly 1100 may include the suction motor 1110 configured to convert an electric force into a mechanical rotational force, the impeller 1120 that rotates by being connected to the suction motor 1110, and the printed circuit board (PCB) 1130 connected to the suction motor 1110. The suction motor 1110 and the impeller 1120 that rotates by being connected to the suction motor 1110 may form vacuum in the vacuum cleaner. Here, the vacuum refers to a state having a pressure lower than atmospheric pressure. The suction motor 1110 may include, but is not limited to, a brushless direct current (BLDC) motor.

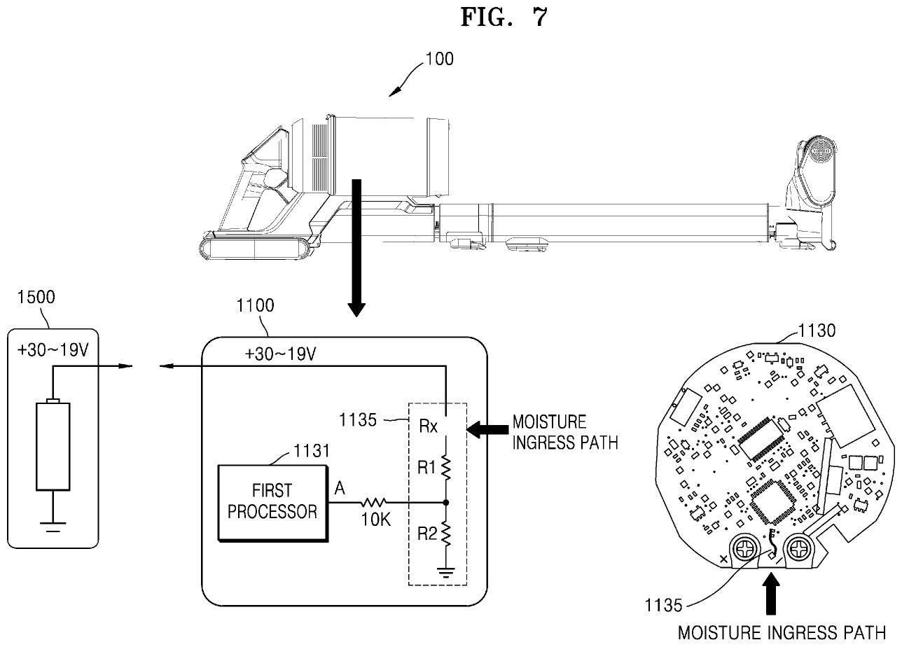

The PCB 1130 may include, but is not limited to, a processor (hereinafter, the first processor 1131) configured to control the suction motor 1110 and control communication with the brush device 2000, a first switch device 1132 connected to a signal line, a switch device (hereinafter, referred to as a pulse-width modulation (PWM) control switch device 1133) used for power supply to the brush device 2000, a load detection sensor 1134 configured to detect a load of the brush device 2000, and the moisture detection circuit 1135 configured to detect moisture introduced into the cleaner body 1000 through a flow path. Here, the first processor 1131 include circuitry and may be implemented as an integrated circuit (IC). The PWM control switch device 1133 may include a field-effect transistor (FET), a Bipolar junction transistor (BJT), or an insulated gate bipolar transistor (IGBT). The load detection sensor 1134 may include a shunt resistor, a shunt resistor and amplification circuit (operational amplifier (OP-AMP)), a current detection sensor, or a magnetic field detection sensor (non-contact manner). Hereinafter, for convenience of description, an embodiment where the PWM control switch device 1133 includes an FET, and the load detection sensor 1134 includes a shunt resistor will be described as an example. The moisture detection circuit 1135 may include a portion that is open when a liquid is not introduced and then forms resistance in response to liquid ingress. The moisture detection circuit 1135 may include a voltage distributing circuit. The moisture detection circuit 1135 may be located between a positive (+) terminal and a negative (−) terminal, which electrically connect the motor assembly 1100 to the battery module 1500. The moisture detection circuit 1135 may be connected to an input port of the first processor 1131 and a positive (+) power line that receives power from the battery module 1500, but an embodiment of the disclosure is not limited thereto. The moisture detection circuit 1135 will be described below in detail with reference to FIGS. 7 and 10 to 11.

The motor assembly 1100 may have an inverted motor structure in which positions of the impeller 1120 and the PCB 1130 are inverted. In the inverted motor structure, the PCB 1130 may be located below the suction motor 1110 and the impeller 1120 may be located above the suction motor 1110 in an air flow direction. Accordingly, the impeller 1120 may be closer to a filter unit 1300 than the PCB 1130.

The first processor 1131 may obtain data related to a state of the suction motor 1110 (referred to as state data) and data on moisture ingress, and may transmit the state data of the suction motor 1110 and the data on the moisture ingress to the main processor 1800. Also, the first processor 1131 may be configured to transmit a signal (hereinafter, a first signal) to the brush device 2000 through the signal line by controlling (e.g., turning on or off) an operation of the first switch device 1132 connected to the signal line. The first switch device 1132 is a device that enables a state of the signal line to become low. For example, the first switch device 1132 is a device that enables a voltage of the signal line to be 0 volt (V). The first signal may include, but is not limited to, data indicating at least one of target RPM of a rotating brush of the brush device 2000 (hereinafter, also referred to as target drum RPM), a target trip level of the brush device 2000, or power consumption of the suction motor 1110. For example, the first signal may include data for controlling an illumination device included in the brush device 2000. The first signal may be implemented with a pre-set number of bits. For example, the first signal may be implemented with 5 bits or 8 bits, and have a transmission period of 10 milliseconds (ms) per bit, but an embodiment of the disclosure is not limited thereto.

The first processor 1131 may be configured to detect a signal (hereinafter, a second signal) transmitted from the brush device 2000 through the signal line. The second signal may include, but is not limited to, data indicating a current state of the brush device 2000. For example, the second signal may include data on a current operation condition (e.g., current drum RPM, a current trip level, and a current illumination device setting value). Also, the second signal may further include data indicating a type of the brush device 2000. The first processor 1131 may be configured to transmit, to the main processor 1800, the data indicating the current state of the brush device 2000 or the data indicating the type of the brush device 2000, included in the second signal.

The motor assembly 1100 may be located in the dust collection container (dust bin) 1200. The dust collection container 1200 may be configured to filter out dust or dirt in air introduced through the brush device 2000, and collect the dust or dirt. The dust collection container 1200 may be provided to be attached to or detached from the cleaner body 1000.

The dust collection container 1200 may collect foreign materials through a cyclone method of separating the foreign materials by using a centrifugal force. The air from which the foreign materials are removed through the cyclone method may be discharged out of the cleaner body 1000, and the foreign materials may be contained in the dust collection container 1200. A multi-cyclone may be located in the dust collection container 1200. The dust collection container 1200 may be provided so that the foreign materials are collected below the multi-cyclone. The dust collection container 1200 may include a dust collection container door (also referred to as a cover of the dust bin 1200) provided so that the dust collection container 1200 is opened when connected to a station. The dust collection container 1200 may include a first dust collecting portion where relatively large foreign materials are primarily collected, and a second dust collecting portion where relatively small foreign materials are collected by the multi-cyclone. The first dust collecting portion and the second dust collecting portion may both be provided to be externally opened when the dust collection container door is opened.

The filter unit 1300 may filter out fine particulate matters and the like, which are not filtered out by the dust collection container 1200. The filter unit 1300 may include a discharge port for discharging air that passed through a filter 197 to the outside of the vacuum cleaner. The filter unit 1300 may include, but is not limited to, a motor filter or a high-efficiency particulate air (HEPA) filter.

The pressure sensor 1400 may measure pressure in a flow path (hereinafter, also referred to as flow path pressure). The pressure sensor 1400 provided at a suction end (e.g., a suction duct 40) may measure a flow rate change at a corresponding location by measuring static pressure. The pressure sensor 1400 may be an absolute pressure sensor or a relative pressure sensor. In an embodiment where the pressure sensor 1400 is an absolute pressure sensor, the main processor 1800 may sense a first pressure value before the suction motor 1110 is operated, by using the pressure sensor 1400. Here the main processor 1800 include circuitry and may be implemented as an IC. Then, the main processor 1800 may sense a second pressure value after the suction motor 1110 is operated at the target RPM, and use a difference between the first pressure value and the second pressure value to sense a pressure value in the flow path. In this case, the first pressure value may be a pressure value corresponding to internal/external influences, such as the weather, an altitude, a state of the vacuum cleaner, and an amount of dust inflow, the second pressure value may be a pressure value corresponding to an operation of the suction motor 1110 and the pressure value corresponding to the internal/external influences, such as the altitude, the state of the vacuum cleaner, and the amount of dust inflow, and the difference between the first pressure value and the second pressure value may be a pressure value corresponding to an operation of the suction motor 1110. Accordingly, in such an embodiment, the difference between the first pressure value and the second pressure value is used to sense the pressure value in the flow path, such that the internal/external influence other than the suction motor 1110 may be reduced.

The flow path pressure measured by the pressure sensor 1400 may be used to identify a current usage environment state of the brush device 2000 (e.g., a state of the surface to be cleaned (a hard floor, a carpet, a mat, or a corner) or a state of being lifted from the surface to be cleaned), and may be used to measure suction power that changes based on a contamination degree or a dust collected degree of the dust collection container 1200.

The pressure sensor 1400 may be located at the suction end (e.g., the suction duct 40). The suction duct 40 may be a structure that connects the dust collection container 1200 and the extension pipe 3000 to each other or the dust collection container 1200 and the brush device 2000 to each other so that a fluid including the foreign materials may move to the dust collection container 1200. Considering contamination of dirt/dust, the pressure sensor 1400 may be located at an end of a straight portion (or an inflection point of the straight portion and a curved portion) of the suction duct 40, but an embodiment of the disclosure is not limited thereto. The pressure sensor 1400 may be located at a center of the straight portion of the suction duct 40. In an embodiment, where the pressure sensor 1400 is located at the suction duct 40, the pressure sensor 1400 is located at a front end of the suction motor 1110 that generates suction power, and thus, the pressure sensor 1400 may be implemented as a negative pressure sensor.

In an embodiment of the disclosure, as described above, the pressure sensor 1400 may be located at the suction duct 40, but an embodiment of the disclosure is not limited thereto. In an embodiment, the pressure sensor 1400 may be located at a discharge port (e.g., in the motor assembly 1100). In such an embodiment where the pressure sensor 1400 is located at the discharge port, the pressure sensor 1400 is located at a rear end of the suction motor 1110, and thus, the pressure sensor 1400 may be implemented as a positive pressure sensor. In an embodiment, a plurality of the pressure sensors 1400 may be provided in the vacuum cleaner.

The battery module 1500 may be detachably mounted on the cleaner body 1000. The battery module 1500 may be electrically connected to a charging terminal provided at the station. The battery module 1500 may be charged by receiving power from the charging terminal. According to an embodiment of the disclosure, the battery module 1500 may include a processor (e.g., a micro-computer, a microprocessor computer or a microprocessor controller (MICOM)) for controlling a voltage supplied to the cleaner body 1000 and communicating with the main processor 1800. The battery module 1500 may perform data communication with the main processor 1800. The battery module 1500 may periodically transmit information such as a battery charge state and an output voltage to the main processor 1800.

The battery module 1500 may include an light emitting diode (LED) display for indicating charging, discharging, or state of a battery. For example, the LED display may display red, orange, or yellow corresponding to a charging rate, and then display green when charging is completed.

The communication interface 1600 may include a module for communicating with an external device. For example, the cleaner body 1000 may communicate with the station or a server device through the communication interface 1600. The communication interface 1600 may include a short-range wireless communication interface and a long-range wireless communication interface. Examples of the short-range wireless communication interface may include, but are not limited to, a Bluetooth communication interface, a Bluetooth low energy (BLE) communication interface, a near-field communication (NFC) unit, a wireless local area network (WLAN) (Wi-Fi) communication interface, a Zigbee communication interface, an infrared data association (IrDA) communication interface, a Wi-Fi direct (WFD) communication interface, an ultra-wideband (UWB) communication interface, and an Ant+communication interface. The long-range wireless communication interface may be used for the cleaner body 1000 to remotely communicate with a server. Examples of the long-range wireless communication interface may include the Internet, a computer network (e.g., LAN or WAN), and a mobile communication interface. Examples of the mobile communication interface may include, but are not limited to, a 3G module, a 4G module, a 5G module, an LTE module, an NB-IoT module, and an LTE-M module.

The user interface 1700 may be provided at a handle. The user interface 1700 may include an input interface and an output interface. The cleaner body 1000 may receive a user input related to an operation of the vacuum cleaner or output information related to an operation of the vacuum cleaner, through the user interface 1700. The cleaner body 1000 may output information about an operating state, information about a remaining battery level, information about a docking state, information about a state of the dust bin 1200, information about a state of a dust bag, and information about moisture ingress through the user interface 1700.

The input interface may include at least one of, but not limited to, a motion input unit, a voice input unit (e.g., a microphone), or a manipulation input unit (e.g., a power button or a suction power strength adjusting button). Examples of the output interface may include, but are not limited to, an LED display, a liquid-crystal display (LCD), a touchscreen, and a speaker.

The cleaner body 1000 may include at least one processor 1010. The cleaner body 1000 may include one processor or a plurality of processors. For example, the cleaner body 1000 may include the main processor 1800 connected to the user interface 1700 and the first processor 1131 connected to the suction motor 1110. The at least one processor 1010 may control an overall operation of the vacuum cleaner. For example, the at least one processor 1010 may determine power consumption (suction power strength) of the suction motor 1110, drum RPM of the brush device 2000, and a trip level of the brush device 2000.

The at least one processor 1010 according to an embodiment of the disclosure may include at least one of a central processing unit (CPU), a graphics processing unit (GPU), an accelerated processing unit (APU), a many integrated core (MIC), a digital signal processor (DSP), or a neural processing unit (NPU). The at least one processor 1010 may be implemented in the form of an integrated system-on-chip (SoC) including one or more electronic components. The at least one processor 1010 may each be implemented as separate hardware (H/W). The at least one processor 1010 may be referred to as a MICOM, a micro-processor unit (MPU), or a micro-controller unit (MCU).

The at least one processor 1010 according to an embodiment of the disclosure may be implemented as a single core processor or a multicore processor.

The memory 1900 may store programs for processes and control by the at least one processor 1010, or may store input/output data. For example, the memory 1900 may store a pre-trained artificial intelligence (AI) model (e.g., a support vector machine (SVM) algorithm), state data of the suction motor 1110, a measurement value of the pressure sensor 1400, state data of the battery module 1500, state data of the brush device 2000, error occurrence data (failure history data), power consumption of the suction motor 1110 corresponding to an operation condition, RPM of a drum with a rotating brush, a trip level, an operation sequence of the suction motor 1110 corresponding to a suction power generation pattern, a type of the brush device 2000 corresponding to a voltage value input through the signal line, a PWM frequency for each type of the brush device 2000, an average input voltage for each type of the brush device 2000, a high load reference value (low load reference value) for each type of the brush device 2000, and information about predefined motion patterns (user gestures) in response to a plurality of control commands, and information about moisture ingress into the cleaner body 1000.

The memory 1900 may include an external memory and an internal memory. For example, the memory 1900 may include at least one type of storage medium from among a flash memory type, a hard disk type, a multimedia card micro type, a card type memory (e.g., an SD or XD memory), a random-access memory (RAM), a static random-access memory (SRAM), a read-only memory (ROM), an electrically erasable programmable read-only memory (EEPROM), a programmable read-only memory (PROM), a magnetic memory, a magnetic disk, and an optical disk. Programs stored in the memory 1900 may be classified into a plurality of modules according to their functions.

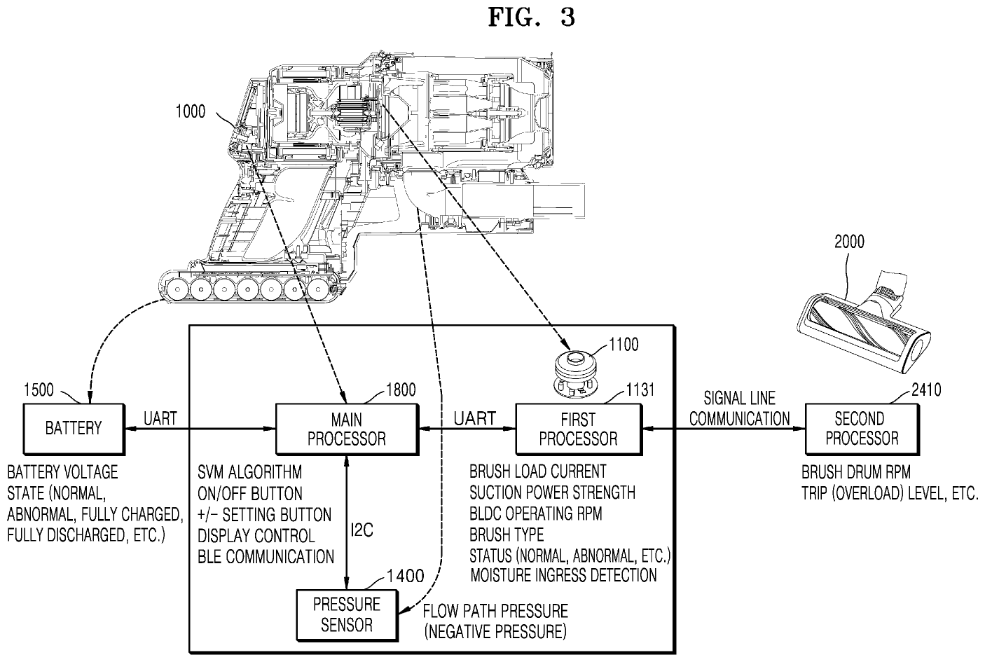

Hereinafter, operations of processors of the vacuum cleaner will be described in detail with reference to FIG. 3.

FIG. 3 is a view for describing operations of processors of a vacuum cleaner, according to an embodiment of the disclosure.

Referring to FIG. 3, in an embodiment, the main processor 1800 may identify states of components in the vacuum cleaner by communicating with the battery module 1500, the pressure sensor 1400, a motion sensor (not shown) (e.g., a gyro sensor or an acceleration sensor), and the first processor 1131 in the motor assembly 1100. In this case, the main processor 1800 may periodically communicate with each component by using, but not limited to, universal asynchronous receiver/transmitter (UART) communication or inter-integrated circuit (I2C) communication. For example, the main processor 1800 may obtain, from the battery module 1500 by using UART communication, data on a voltage state (e.g., normal, abnormal, fully charged, or fully discharged) of a battery. The main processor 1800 may obtain, from the pressure sensor 1400 by using I2C communication, data on flow path pressure. The main processor 1800 may obtain angular velocity data from the gyro sensor (not shown) through UART communication, and may obtain acceleration data from the acceleration sensor (not shown) through I2C communication.

In an embodiment, the main processor 1800 may obtain, from the first processor 1131 connected to the suction motor 1110 by using UART communication, data on suction power strength, RPM of the suction motor 1110, and a state (e.g., normal or abnormal) of the suction motor 1110. Suction power is an electric force consumed to operate the cordless vacuum cleaner 100, and may be referred to as power consumption. The main processor 1800 may obtain, from the first processor 1131, data related to a load of the brush device 2000 and data on a type of the brush device 2000. The main processor 1800 may obtain data about moisture ingress into the cleaner body 1000 from the first processor 1131.

In an embodiment, the first processor 1131 may obtain, from the brush device 2000 through signal line communication with a second processor 2410 of the brush device 2000, state data (e.g., drum RPM, a trip level, normal, or abnormal) of the brush device 2000. In this case, the first processor 1131 may transmit the state data of the brush device 2000 to the main processor 1800 through UART communication. According to an embodiment of the disclosure, the first processor 1131 may transmit, to the main processor 1800, state data of the suction motor 1110 and state data of the brush device 2000 at different intervals. For example, the first processor 1131 may transmit the state data of the suction motor 1110 to the main processor 1800 every 0.02 seconds, and transmit the state data of the brush device 2000 to the main processor 1800 every 0.2 seconds, but an embodiment of the disclosure is not limited thereto.

The main processor 1800 may determine whether an error occurs based on states of components in the cordless vacuum cleaner 100, a state of the suction motor 1110, and a state of the brush device 2000, and may periodically transmit, to a station device, data related to the occurrence of the error through short-range wireless communication (e.g., BLE communication).

In an embodiment where the first processor 1131 of the cleaner body 1000 and the second processor 2410 of the brush device 2000 are connected to each other through UART communication or I2C communication, a high impedance effect caused by an internal line of the extension pipe, and burnout of a circuit element (e.g., a maximum value excess of a MICOM AD port) caused by electrostatic discharge (ESD) and/or overvoltage may occur. Accordingly, in an embodiment of the disclosure, the first processor 1131 of the cleaner body 1000 and the second processor 2410 of the brush device 2000 may communicate with each other through signal line communication instead of UART communication or I2C communication. In this case, a circuit for signal line communication may include a voltage distributing circuit (hereinafter, referred to as a voltage distributer) to prevent the burnout of the circuit element caused by overvoltage, power noise, or surge, electrical overstress (EOS), or electrostatic discharge (ESD). However, communication between the first processor 1131 of the cleaner body 1000 and the second processor 2410 of the brush device 2000 is not limited to signal line communication.

According to an embodiment of the disclosure, where a noise reduction circuit is applied to the cleaner body 1000 and the brush device 2000, the first processor 1131 of the cleaner body 1000 and the second processor 2410 of the brush device 2000 may communicate with each other through UART communication or I2C communication. The noise reduction circuit may include at least one of, but not limited to, a low-pass filter, a high-pass filter, a band-pass filter, a damping resistor, or a distribution resistor. According to an embodiment of the disclosure, where a level shifter circuit is applied to the cleaner body 1000 or the brush device 2000, the first processor 1131 of the cleaner body 1000 and the second processor 2410 of the brush device 2000 may communicate with each other through UART communication or I2C communication. For convenience of description, embodiments where the cleaner body 1000 and the brush device 2000 communicate with each other through signal line communication will hereinafter be described.

In an embodiment, the main processor 1800 may receive a user input on a setting button (e.g., an ON/OFF button or a +/−setting button) included in the user interface 1700 or control an output of an LCD. The main processor 1800 may identify a usage environment state (e.g., a state of a surface to be cleaned (a hard floor, a carpet, a mat, or a corner) and a state of being lifted from the surface to be cleaned), by using a pre-trained AI model (e.g., a support vector machine (SVM) algorithm), and determine operation information (e.g., power consumption, drum RPM, or a trip level of the suction motor 1110) of the cordless vacuum cleaner 100 suitable for the usage environment state of the brush device 2000. In this case, the main processor 1800 may transmit, to the first processor 1131, the operation information of the cordless vacuum cleaner 100 suitable for the usage environment state of the brush device 2000. The first processor 1131 may adjust the strength of suction power (power consumption or RPM) of the suction motor 1110 according to the operation information of the cordless vacuum cleaner 100, and transmit the operation information of the cordless vacuum cleaner 100 suitable for the usage environment state of the brush device 2000, to the second processor 2410 through signal line communication. In this case, the second processor 2410 may adjust drum RPM, a trip level, and an illumination device (e.g., an LED display) based on the operation information of the cordless vacuum cleaner 100.

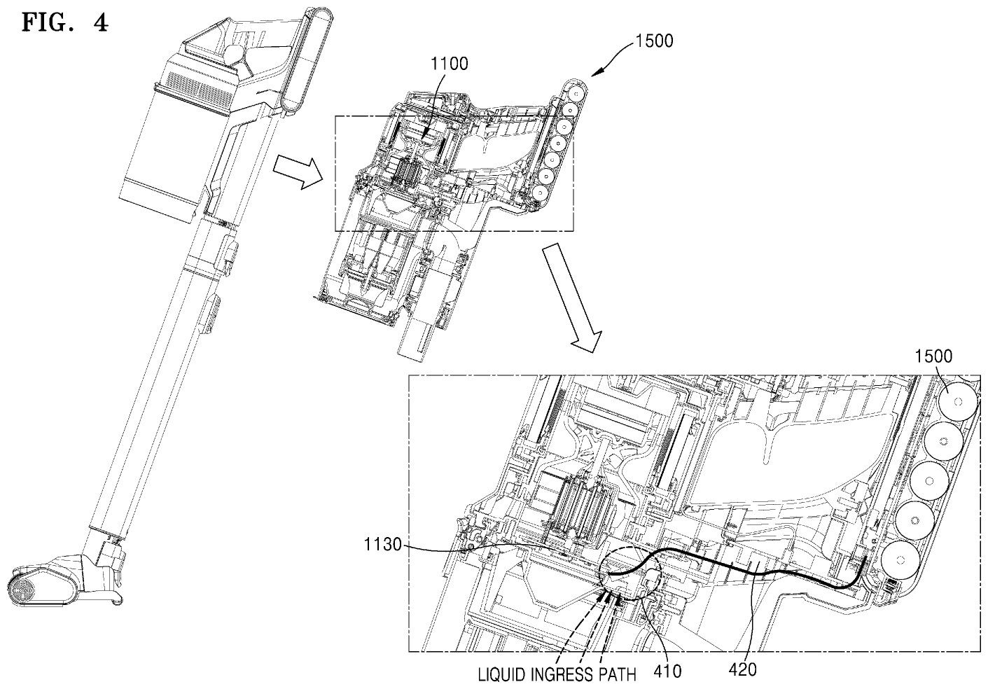

When it is determined that moisture is introduced into the cleaner body 1000 through the moisture detection circuit 1135, the main processor 1800 may transmit a signal indicating to stop driving of the suction motor 1110, to prevent circuit burnout and insulation tracking. Hereinafter, a moisture (liquid) ingress path will be described with reference to FIG. 4.

FIG. 4 is a view for describing a moisture ingress path, according to an embodiment of the disclosure.

Referring to FIG. 4, when a liquid is sucked up from a surface to be cleaned during cleaning using the cordless vacuum cleaner 100, the sucked liquid (e.g., water, dirt, etc.) flows under the suction motor 1110 and gathers in a battery fastening portion 410 at a lower end of the PCB 1130. The battery fastening portion 410 may be a portion where the motor assembly 1100 and a battery fastening line 420 (e.g., wire harness) are connected. The battery fastening portion 410 may include a positive (+) terminal and a negative (−) terminal.

According to an embodiment of the disclosure, in the motor assembly 1100 having an inverted structure, because the PCB 1130 is located in front of a suction flow path, components included in the PCB 1130 are likely to be burned out when the sucked liquid gathers in the battery fastening portion 410 at the lower end of the PCB 1130. Also, because the battery fastening portion 410 that connects battery power is located under the PCB 1130, when a liquid (moisture) is applied (introduced) to a high voltage/high current terminal, insulation tracking may occur between the positive (+) terminal and the negative (−) terminal, which may lead to fire or ignition.

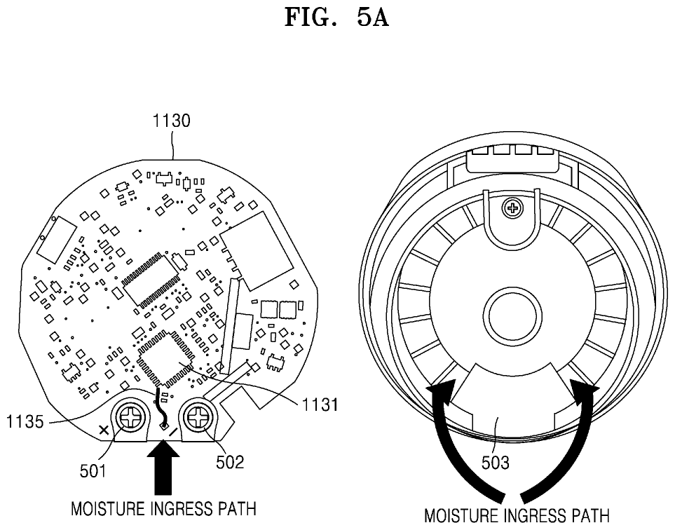

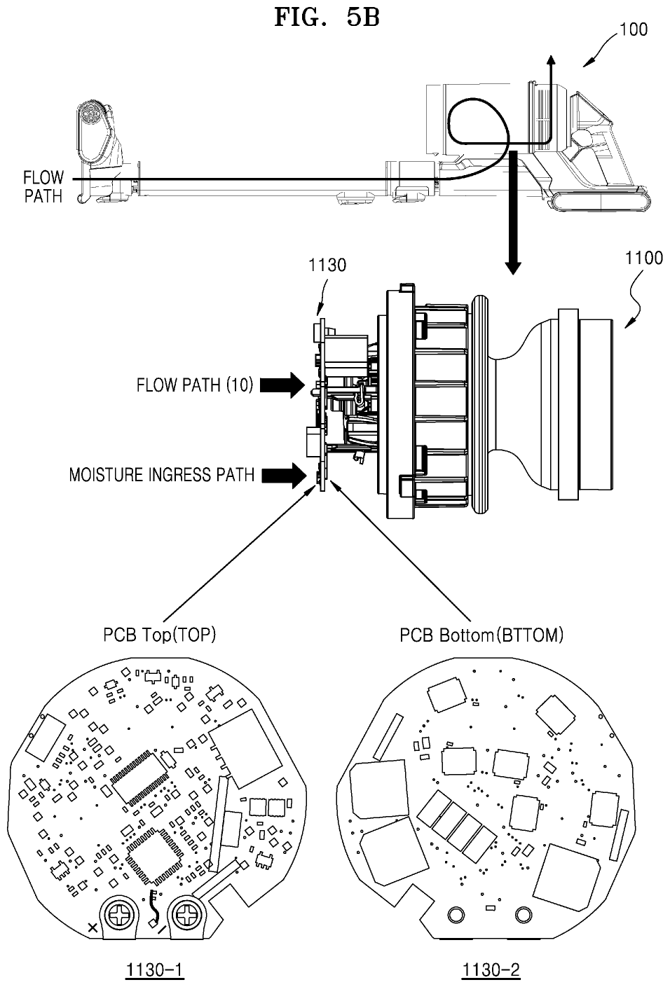

Accordingly, in order to prevent component burnout and insulation tracking, the moisture detection circuit 1135 for detecting liquid ingress into the PCB 1130 may be desired to be provided. Hereinafter, a position of the moisture detection circuit 1135 will be described in detail with reference to FIGS. 5A and 5B.

FIG. 5A is a view for describing the moisture detection circuit 1135, according to an embodiment of the disclosure.

When a liquid is sucked up from a surface to be cleaned during cleaning using the cordless vacuum cleaner 100, the sucked liquid (e.g., water, dirt, etc.) flows under the suction motor 1110 and then gathers at a lower end of the PCB 1130. Even when a guard device (e.g., a cap grille 503) is applied to a front portion of the PCB 1130, when a large amount of liquid is introduced, the liquid may pass through the cap grille 503 and gather at a lower end of the PCB 1130.

Accordingly, referring to FIG. 5A, the moisture detection circuit 1135 may be provided at a lower end of the PCB 1130 by considering a moisture ingress path. For example, the moisture detection circuit 1135 may be located between a positive (+) terminal 501 and a negative (−) terminal 502, which electrically connect the motor assembly 1100 to the battery module 1500. In this case, the moisture detection circuit 1135 may be connected to an input port of the first processor 1131 included in the PCB 1130, and the first processor 1131 may detect whether there is moisture ingress based on a voltage value input to the input port through the moisture detection circuit 1135. A configuration of the moisture detection circuit 1135 will be described below in detail with reference to FIG. 7.

Referring to an embodiment of the disclosure, the input port of the first processor 1131 may be implemented as a general purpose input output (GPIO) port, or may be implemented as an analog-to-digital (AD) port (also referred to as an analog-to-digital converter (ADC)).

FIG. 5B is a view for describing a position of the moisture detection circuit 1135, according to an embodiment of the disclosure.

According to an embodiment of the disclosure, the moisture detection circuit 1135 may be provided on a top surface (or a front surface) 1130-1 of the PCB 1130, or may be provided on a bottom surface (or a rear surface) 1130-2 of the PCB 1130.

When liquid is introduced into the cleaner body 1000, the liquid first reaches the top surface 1130-1 of the PCB 1130. Accordingly, in an embodiment where the moisture detection circuit 1135 is provided on the top surface 1130-1 of the PCB 1130, the vacuum cleaner may rapidly detect moisture ingress.

According to an embodiment of the disclosure, because sucked dust may be accumulated on the top surface 1130-1 of the PCB 1130, there is a possibility of erroneous detection. Accordingly, in an embodiment, the moisture detection circuit 1135 may be applied to the bottom surface 1130-2 of the PCB 1130.

FIG. 6 is a flowchart for describing a method of controlling driving of the suction motor 1110 based on moisture ingress, according to an embodiment of the disclosure.

In operation S610, a vacuum cleaner according to an embodiment of the disclosure may monitor whether there is moisture ingress into the cleaner body 1000 by using the moisture detection circuit 1135.

A configuration of the moisture detection circuit 1135 will be described with reference to FIG. 7. FIG. 7 is a view for describing the moisture detection circuit 1135, according to an embodiment of the disclosure. Referring to FIG. 7, an embodiment of the moisture detection circuit 1135 may include three resistors. In an embodiment, for example, the moisture detection circuit 1135 may include resistors Rx, R1, and R2. Mounting positions of the resistors included in the moisture detection circuit 1135 according to an embodiment of the disclosure in the PCB 1130 may be determined based on a predefined moisture detection sensitivity or a flow path structure (moisture ingress path) inside the cleaner body 1000, a shape (or structure) of a guard device (e.g., the cap grille 503) located on a front portion of the PCB 1130, a suction power strength, etc.

The resistor Rx resists a liquid introduced into the cleaner body 1000 and is located in a liquid ingress path. In FIG. 7, a value of the resist Rx when moisture is not introduced into the cleaner body 1000 is infinite (∞).

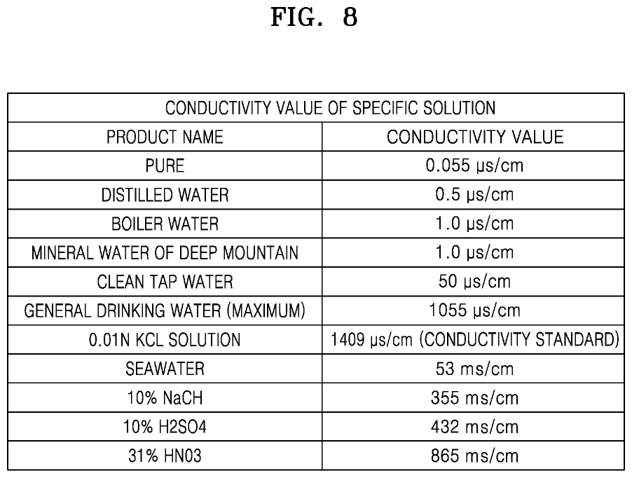

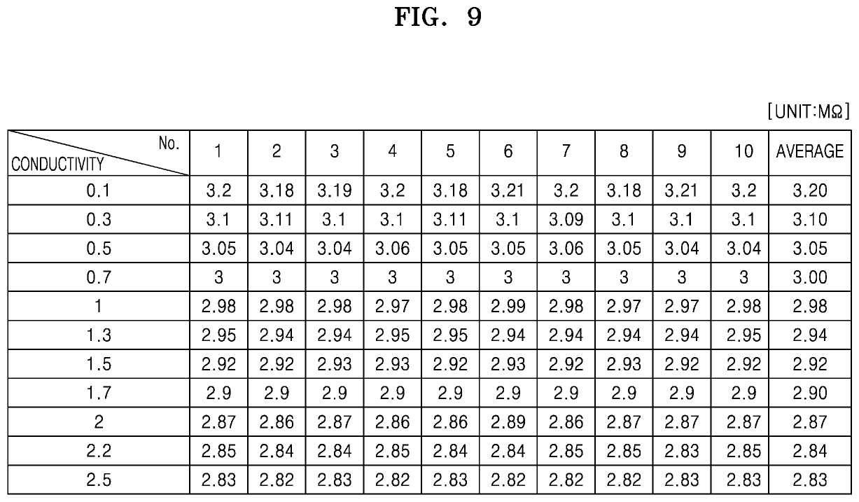

A value of the resistor Rx may vary according to a type of a liquid (or an electrical conductivity of a liquid). Referring to FIG. 8, an electrical conductivity of pure water may be 0.055 microsecond per centimeter (μs/cm), an electrical conductivity of distilled water may be 0.5 μs/cm, an electrical conductivity of tap water may be 50 μs/cm, and an electrical conductivity of seawater may be 53 ms/cm. Referring to FIG. 9, a value of the resistor Rx may decrease as an electrical conductivity of a liquid increases, and a value of the resistor Rx may increase as an electrical conductivity of a liquid decreases. For example, an average resistance value of a liquid having an electrical conductivity of 0.1 ms/cm may be 3.20 megaohms (MΩ), an average resistance value of a liquid having an electrical conductivity of 0.5 ms/cm may be 3.05 MΩ, and an average resistance value of a liquid having an electrical conductivity of 1 ms/cm may be 2.98 MΩ.

Referring back to FIG. 7, a portion where the resistor Rx is located is a portion that is disconnected (open portion) when a liquid is not introduced, and a circuit may be connected through a liquid when the liquid is introduced. Accordingly, a voltage input to an input port of the first processor 1131 when a liquid is not introduced may be 0 V (low). On the other hand, when a liquid is introduced, because a value of the resistor Rx is determined by a type of the introduced liquid (electrical conductivity), a voltage value input to the input port of the first processor 1131 may vary based on a type of a liquid.

When a liquid is introduced, a voltage input to the input port of the first processor 1131 may be as follows.

Input voltage=Vin(battery voltage)×R2/(R11+R2+Rx),

According to an embodiment of the disclosure, at least one processor 1010 may determine whether there is moisture ingress into the cleaner body 1000 based on a result of comparing a voltage value input through the moisture detection circuit 1135 with a reference voltage value. For example, when the voltage value input through the moisture detection circuit 1135 is equal to or greater than the reference voltage value, the at least one processor 1010 may determine that there is moisture ingress into the cleaner body 1000. The at least one processor 1010 may be the first processor 1131 or the main processor 1800.

The reference voltage value may be a voltage value based on a value of the resistor Rx of a reference liquid affecting component burnout or insulation tracking. The reference voltage value may vary based on a moisture detection sensitivity or a reference liquid. For example, when the moisture detection sensitivity is set low, the reference voltage value may increase, and when the moisture detection sensitivity is set high, the reference voltage value may decrease. Also, when the reference liquid is a liquid (e.g., seawater) having a high electrical conductivity, the reference voltage value may increase, and when the reference liquid is a liquid (e.g., pure water) having a low electrical conductivity, the reference voltage value may decrease.

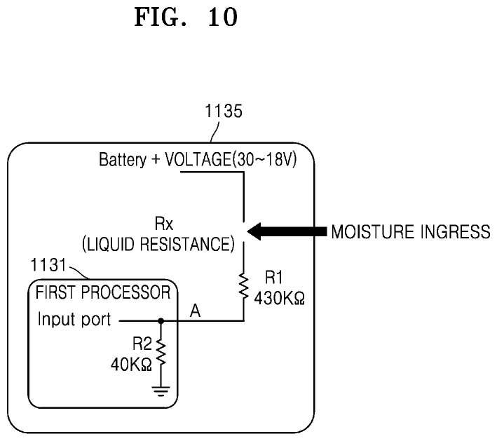

A specific example of an operation in which the first processor 1131 detects whether there is moisture ingress will be described with reference to FIG. 10. Referring to FIG. 10, the resistor R2 may be implemented as a pull-down resistor in the first processor 1131.

Although a value (e.g., a resistance or time constant) of the resistor R1 is 430 kiloohm (kΩ), a value of the resistor R2 is 40 kΩ, and a reference voltage value is 1.85 V in FIG. 10, an embodiment of the disclosure is not limited thereto. When the input port of the first processor 1131 is an AD port, a reference voltage value may vary based on a moisture detection sensitivity. Also, when the input port of the first processor 1131 is a GPIO port, values of the resistor R1 and the resistor R2 may vary (or be variously determined or set) based on a moisture detection sensitivity.

A voltage input to the input port of the first processor 1131 may be as follows.

$$\begin{matrix}Input Port A = Battery Input voltage \times \{ R 2 / ( Rx + R 1 + R 2 ) \} \\ = Battery input voltage \times \{ 40 K Ω / ( Rx + 430 k Ω + 40 k Ω ) \} \\ = Battery input voltage \times \{ 40 K Ω / ( Rx + 470 k Ω ) \}\end{matrix}$$

A value of the resistor Rx when a voltage input to the input port is the reference voltage value (1.85 V) is calculated as follows.

$$\begin{matrix}Rx = 40 k Ω \times \{ Battery input voltage / reference voltage value ( 1.85 V ) \} - \\ 470 k Ω \\ = 40 k Ω \times ( 30 V / 1.85 V ) - 470 k Ω , if battery voltage 30 V \\ = 178.6486 k Ω\end{matrix}$$

That is, when a resistance value of an introduced liquid is equal to or less than 178.6 kΩ, because a voltage value input to the input port is equal to or greater than the reference voltage value (e.g., 1.85 V), the first processor 1131 may determine that there is liquid ingress into the cleaner body 1000. On the other hand, when a liquid is not introduced or a resistance value of an introduced liquid is equal to or greater than 178.7 kΩ, because a voltage value input to the input port is less than the reference voltage value (e.g., 1.85 V), the first processor 1131 may determine that a liquid affecting component damage or insulation tracking is not introduced into the cleaner body 1000.

A resistance value (e.g., 178.6 kΩ) of the resistor Rx with respect to an introduced liquid in the above equation may vary based on a magnitude of a battery input voltage.

According to an embodiment of the disclosure, assuming that the input port of the first processor 1131 is a GPIO port, when a liquid is not introduced or a resistance value of an introduced liquid is equal to or greater than 178.7 kΩ, a signal indicating “Low” may be input to the input port of the first processor 1131, and when a resistance value of an introduced liquid is equal to or less than 178.6 kΩ, a signal indicating “High” may be input to the input port of the first processor 1131.

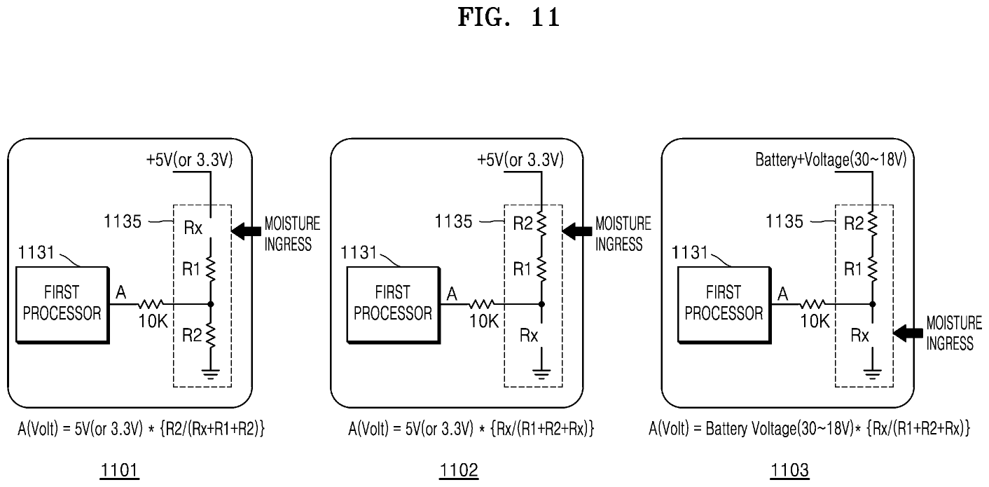

A type of the moisture detection circuit 1135 is not limited to that shown in FIG. 10. The moisture detection circuit 1135 may be implemented in any of various types. FIG. 11 is a view for describing various types of moisture detection circuits 1135, according to an embodiment of the disclosure.

Referring to 1101 of FIG. 11, in an embodiment, the moisture detection circuit 1135 may be connected to an output line (e.g., 5 V or 3.3 V) of a DC/DC converter, instead of a positive (+) power line (e.g., +30 to 19 V) of the battery module 1500. In this case, when there is no liquid ingress into the cleaner body 1000, “0V” or a signal indicating “Low” may be input to the input port (e.g., an A port) of the first processor 1131. On the other hand, when there is moisture ingress into the cleaner body 1000, a value corresponding to an “output voltage (e.g., 5 V or 3.3 V)×{R2/(Rx+R1+R2)}” or a signal indicating “High” may be input to the input port of the first processor 1131. Accordingly, when a voltage value input to the input port is equal to or greater than a reference voltage value, the first processor 1131 may determine that moisture has been introduced into the cleaner body 1000, and when a voltage value input to the input port is less than the reference voltage value, the first processor 1131 may determine that moisture affecting component burnout or insulation tracking has not been introduced into the cleaner body 1000.

Referring to 1102 of FIG. 11, in an embodiment, the resistor Rx with a value varying in response to liquid ingress may be connected to a ground (GND) side instead of the positive (+) power line side. In this case, when there is no liquid ingress into the cleaner body 1000, “5 V (or 3.3 V)” or a signal indicating “High” may be input to the input port (e.g., the A port) of the first processor 1131. On the other hand, when there is liquid ingress into the cleaner body 1000, a value corresponding to an “output voltage of the DC/DC converter (e.g., 5V or 3.3V)×Rx/(R1+R2+Rx)” or a signal indicating “Low” may be input to the input port (e.g., the A port) of the first processor 1131. When a voltage value input to the input port of the first processor 1131 is equal to or less than a reference voltage value, the first processor 1131 may determine that moisture has been introduced into the cleaner body 1000, and when a voltage value input to the input port is greater than the reference voltage value, the first processor 1131 may determine that moisture affecting component burnout or insulation tracking has not been introduced into the cleaner body 1000.

Referring to 1103 of FIG. 11, in an embodiment, the moisture detection circuit 1135 may be connected to the positive (+) power line (e.g., +30 to 18 V) of the battery module 1500, and the resistor Rx may be connected to the ground (GND) side. In this case, when there is no liquid ingress into the cleaner body 1000, a signal indicating “High” may be input to the input port (e.g., the A port) of the first processor 1131. On the other hand, when there is liquid ingress into the cleaner body 1000, a value corresponding to “battery voltage (e.g., 30 V to 18 V)×Rx/(R1+R2+Rx)” or a signal indicating “Low” may be input to the input port (e.g., the A port) of the first processor 1131. Accordingly, when a voltage value input to the input port is equal to or less than a reference voltage value, the first processor 1131 may determine that moisture has been introduced into the cleaner body 1000, and when a voltage value input to the input port is greater than the reference voltage value, the first processor 1131 may determine that moisture affecting component damage or insulation tracking has not been introduced into the cleaner body 1000.

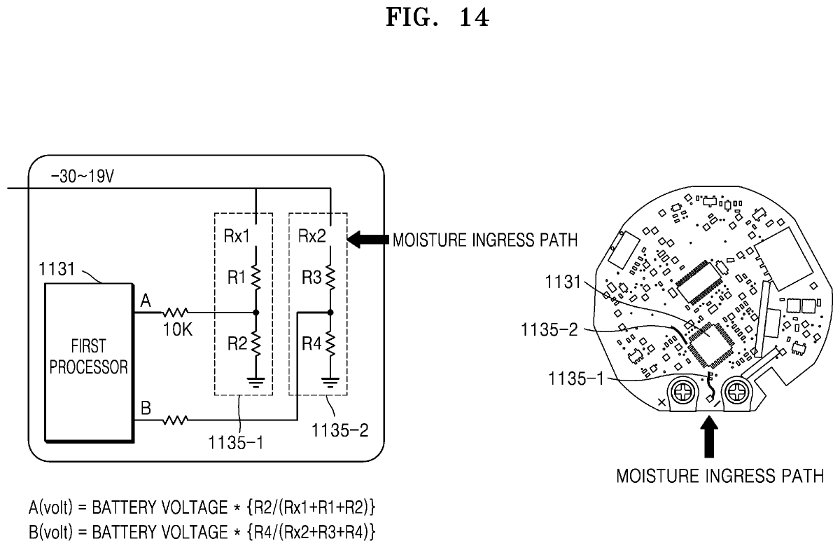

According to an embodiment of the disclosure, a plurality of moisture detection circuits 1135 may be provided. An embodiment in which the PCB 1130 of the motor assembly 1100 includes a plurality of moisture detection circuits 1135 will be described below in detail with reference to FIG. 14.

Referring back to FIG. 6, in operation S620, the vacuum cleaner according to an embodiment of the disclosure may determine whether moisture has been introduced into the cleaner body 1000 by using the moisture detection circuit 1135.

According to an embodiment of the disclosure, when it is determined that moisture has not been introduced into the cleaner body 1000 (No in operation S620), the at least one processor 1010 may continue to monitor whether there is moisture ingress by using the moisture detection circuit 1135. For example, the first processor 1131 may continuously determine whether moisture has been introduced into the cleaner body 1000 based on a result of comparing a voltage value input to the input port through the moisture detection circuit 1135 with a reference voltage value. Also, the first processor 1131 may periodically transmit a signal about whether moisture ingress is detected to the main processor 1800.

In operation S630, the vacuum cleaner according to an embodiment of the disclosure may stop driving of the suction motor 1110 when it is detected that moisture has been introduced into the cleaner body 1000 (Yes in operation S620).

According to an embodiment of the disclosure, the at least one processor 1010 may stop driving of the suction motor 1110 when it is determined that moisture has been introduced into the cleaner body 1000 through the moisture detection circuit 1135. For example, when the first processor 1131 of the motor assembly 1100 identifies that moisture has been introduced into the cleaner body 1000 based on a result of comparing the voltage value input to the input port with the reference voltage value, the first processor 1131 may transmit information indicating that moisture has been introduced into the cleaner body 1000 to the main processor 1800. In this case, the main processor 1800 may transmit a signal indicating to stop driving of the suction motor 1110 to the first processor 1131 of the motor assembly 1100. The first processor 1131 of the motor assembly 1100 may stop driving of the suction motor 1110 in response to the signal received from the main processor 1800, thereby effectively preventing burnout and insulation tracking of components included in the PCB 1130 of the motor assembly 1100.

In operation S640, the vacuum cleaner according to an embodiment of the disclosure may store, in the memory 1900, information indicating that driving of the suction motor 1110 has been stopped due to moisture ingress. For example, the main processor 1800 may store, in the memory 1900, information indicating that driving of the suction motor 1110 has been stopped due to moisture ingress into the cleaner body 1000.

In operation S650, the vacuum cleaner according to an embodiment of the disclosure may output, through an output interface, a notification message indicating that moisture has been introduced into the cleaner body 1000.

According to an embodiment of the disclosure, the vacuum cleaner may visually output through a display (e.g., LCD or LED) or audibly output through a speaker the notification message indicating that moisture has been introduced into the cleaner body 1000.

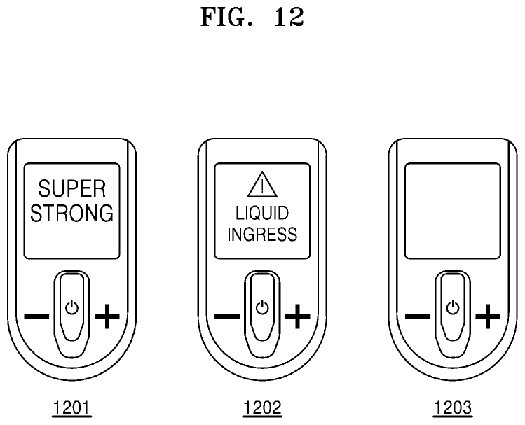

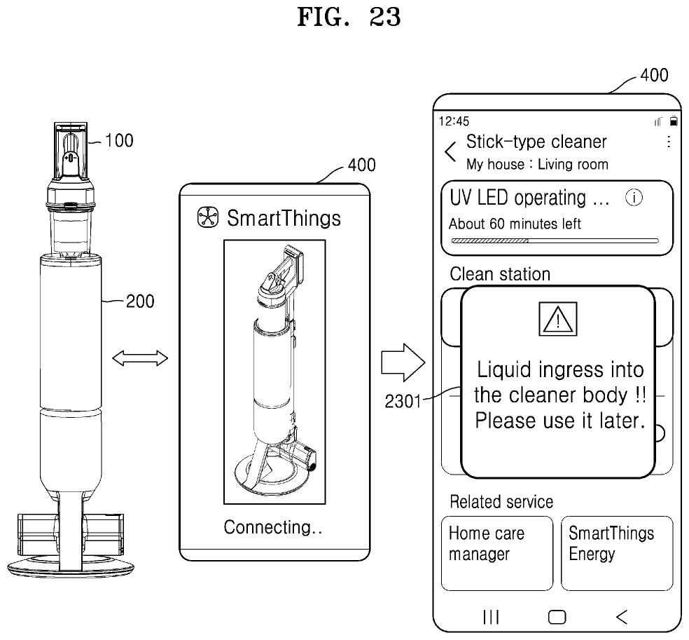

According to an embodiment of the disclosure, the vacuum cleaner may cause a user terminal connected through a server to output the notification message indicating that moisture has been introduced into the cleaner body 1000. An operation in which a user terminal outputs a notification message will be described below in detail with reference to FIG. 23. Hereinafter, an operation in which the cleaner body 1000 outputs a notification message will be described in more detail with reference to FIG. 12.

FIG. 12 is a view for describing an operation in which a vacuum cleaner outputs a notification, according to an embodiment of the disclosure.

Referring to 1201 of FIG. 12, the cleaner body 1000 according to an embodiment of the disclosure may display an operation mode on a display during a cleaning operation. For example, when the cleaner body 1000 operates in a super strong mode, the cleaner body 1000 may display ‘super power’ on the display (e.g., LCD).

Referring to 1202 of FIG. 12, when the cleaner body 1000 according to an embodiment of the disclosure detects that moisture has been introduced into the cleaner body 1000 through the moisture detection circuit 1135 during a cleaning operation, the cleaner body 1000 may stop driving of the suction motor 1110 and may display a notification message on the display (e.g., LCD). For example, the cleaner body 1000 may notify a user of the reason why driving of the suction motor 1110 has been stopped by displaying ‘liquid ingress’ on the display.

Referring to 1203 of FIG. 12, the main processor 1800 of the cleaner body 1000 according to an embodiment of the disclosure may store information indicating that moisture has been introduced into the cleaner body 1000 in the memory 1900, may display a notification message on the display, and then may turn off the power of the cleaner body 1000 by transmitting a signal indicating to stop all outputs to the battery module 1500.

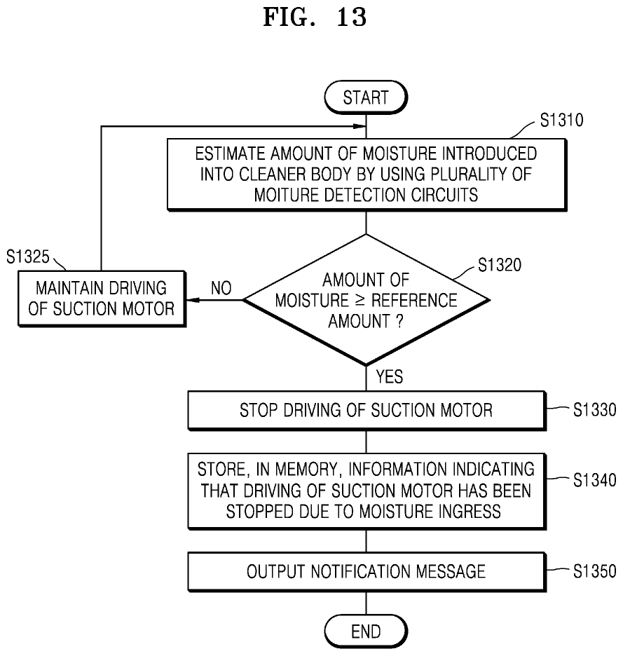

According to an embodiment of the disclosure, the vacuum cleaner may include a plurality of moisture detection circuits 1135. Hereinafter, a method by which a vacuum cleaner measures the amount of moisture introduced into the cleaner body 1000 by using a plurality of moisture detection circuits 1135 will be described with reference to FIG. 13.

FIG. 13 is a flowchart for describing a method of determining the amount of moisture introduced into the cleaner body 1000, according to an embodiment of the disclosure.

In operation S1310, a vacuum cleaner according to an embodiment of the disclosure may estimate the amount of moisture introduced into the cleaner body 1000 by using a plurality of moisture detection circuits 1135.

According to an embodiment of the disclosure, the PCB 1130 of the motor assembly 1100 may include the plurality of moisture detection circuits 1135 designed at different heights. In an embodiment, the number of moisture detection circuits 1135 may be 2, or 3 or more.

Referring to FIG. 14, the motor assembly 1100 may include a first moisture detection circuit 1135-1 and a second moisture detection circuit 1135-2 located at different heights in the PCB 1130. Here, a height of a moisture detection circuit may be defined as a distance of the resistor Rx1 or Rx2 therein from the moisture ingress path.

In this case, the second moisture detection circuit 1135-2 may be located at a higher position than the first moisture detection circuit 1135-1.

When moisture is introduced to a first height at which the first moisture detection circuit 1135-1 is located, a first voltage value input to an input port (e.g., an A port) of the first processor 1131 through the first moisture detection circuit 1135-1 may be “battery voltage×{R2/(Rx1+R1+R2)}”.

Also, when moisture is introduced to a second height at which the second moisture detection circuit 1135-2 is located, a voltage value input to an input port (e.g., a B port) of the first processor 1131 through the second moisture detection circuit 1135-2 may be “battery voltage×{R4/(Rx2+R3+R4)}”.

Accordingly, at least one processor 1010 may estimate the amount of moisture introduced into the cleaner body 1000 through a flow path, by using the first moisture detection circuit 1135-1 and the second moisture detection circui9t 1135-2. For example, when the first voltage value input to the input port (e.g., the A port) through the first moisture detection circuit 1135-1 is less than a reference voltage value, the first processor 1131 may determine that a liquid affecting component burnout or insulation tracking has not been introduced into the cleaner body 1000. Also, when the first voltage value input to the input port (e.g., the A port) through the first moisture detection circuit 1135-1 is equal to or greater than the reference voltage value and a second voltage value input to the input port (e.g., the B port) through the second moisture detection circuit 1135-2 is less than the reference voltage value, the first processor 1131 may determine that a liquid affecting component burnout or insulation tracking has been introduced by an amount corresponding to a height or position between the first height and the second height. Also, when the first voltage value input to the input port (e.g., the A port) through the first moisture detection circuit 1135-1 is equal to or greater than the reference voltage value and the second voltage value input to the input port (e.g., the B port) through the second moisture detection circuit 1135-2 is equal to or greater than the reference voltage value, the first processor 1131 may determine that a liquid affecting component burnout or insulation tracking has been introduced by an amount corresponding to the second height or higher.

In operation S1320, the vacuum cleaner according to an embodiment of the disclosure may determine whether the amount of moisture introduced into the cleaner body 1000 is equal to or greater than a reference amount.

For example, when the reference amount is an amount corresponding to the second height at which the second moisture detection circuit 1135-2 is located, at least one processor 1010 of the cleaner body 1000 may determine whether the second voltage value input to the input port (e.g., the B port) through the second moisture detection circuit 1135-2 is equal to or greater than the reference voltage value. When the second voltage value input to the input port (e.g., the B port) through the second moisture detection circuit 1135-2 is equal to or greater than the reference voltage value, the at least one processor 1010 may determine that the amount of moisture introduced into the cleaner body 1000 is equal to or greater than the reference amount.

In operation S1325, the vacuum cleaner may maintain driving of the suction motor 1110, when the amount of moisture introduced into the cleaner body 1000 is less than the reference amount. The vacuum cleaner may continue to monitor the amount of moisture introduced into the cleaner body 1000 by using a plurality of moisture detection circuits.

In operation S1330, the vacuum cleaner according to an embodiment of the disclosure may stop driving of the suction motor 1110 when the amount of moisture introduced into the cleaner body 1000 is equal to or greater than the reference amount.

For example, when the first processor 1131 of the motor assembly 1100 detects that moisture equal to or greater than the reference amount has been introduced into the cleaner body 1000 by using the plurality of moisture detection circuits 1135, the first processor 1131 may transmit information indicating that moisture has been introduced into the cleaner body 1000 to the main processor 1800. In this case, the first processor 1131 of the motor assembly 1100 may receive a signal indicating to stop driving of the suction motor 1110 from the main processor 1800. The first processor 1131 of the motor assembly 1100 may stop driving of the suction motor 1110 according to the signal received from the main processor 1800, thereby preventing burnout and insulation tracking of components included in the PCB 1130 of the motor assembly 1100.

At a low level of suction power, even when there is a large amount of liquid on a surface to be cleaned, the liquid may not be sucked up to the moisture detection circuit 1135, and at a high level of suction power, even when there is a small amount of liquid on the surface to be cleaned, the liquid may be sucked up to the moisture detection circuit 1135. Accordingly, assuming that an operation mode of the vacuum cleaner is a maximum suction power mode (e.g., a super strong mode or a jet mode), the vacuum cleaner may maintain driving of the suction motor 1110 when the amount of moisture introduced into the cleaner body 1000 is less than the reference amount and may stop driving of the suction motor 1110 when the amount of moisture introduced into the cleaner body 1000 is equal to or greater than the reference amount.

In operation S1340, when driving of the suction motor 1110 has been stopped, the vacuum cleaner according to an embodiment of the disclosure may store information indicating that driving of the suction motor 1110 has been stopped due to moisture ingress in the memory 1900.

In operation S1350, when driving of the suction motor 1110 has been stopped, the vacuum cleaner according to an embodiment of the disclosure may output a notification message indicating that moisture has been introduced into the cleaner body 1000.

According to an embodiment of the disclosure, the vacuum cleaner may visually output through a display (e.g., LCD or LED) or may audibly output through a speaker the notification message indicating that moisture has been introduced into the cleaner body 1000.

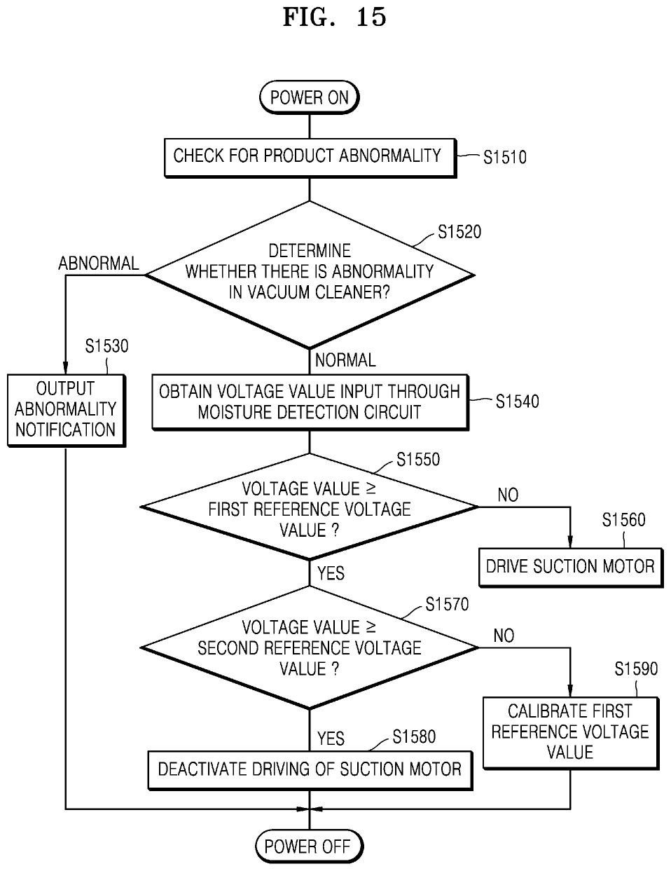

According to an embodiment of the disclosure, the cleaner body 1000 may determine whether moisture has been introduced into the cleaner body 1000 before driving of the suction motor 1110. A method by which the vacuum cleaner detects moisture ingress before driving of the suction motor 1110 will be described in detail with reference to FIG. 15.

FIG. 15 is a flowchart for describing a method of detecting moisture ingress before driving of the suction motor 1110, according to an embodiment of the disclosure.

In operation S1510, a vacuum cleaner according to an embodiment of the disclosure may check for a product abnormality before driving of the suction motor 1110 when the power is turned on.

For example, the main processor 1800 may check a state (e.g., an abnormality) of the battery module 1500 by communicating with the battery module 1500. The main processor 1800 may check a state of the suction motor 1110 and a state of the brush device 2000 by communicating with the motor assembly 1100. The main processor 1800 may check a state of at least one sensor by communicating with the at least one sensor (e.g., the pressure sensor 1400).

In operation S1520, the vacuum cleaner according to an embodiment of the disclosure may determine whether there is an abnormality in the vacuum cleaner as a result of checking for a product abnormality. For example, the main processor 1800 of the cleaner body 1000 may determine whether the battery module 1500 is abnormal, whether the suction motor 1110 is abnormal, whether the brush device 2000 is abnormal, and whether the pressure sensor 1400 is abnormal.

In operation S1530, when there is an abnormality in the vacuum cleaner, the vacuum cleaner according to an embodiment of the disclosure may visually or audibly output an abnormality notification. For example, when there is a product abnormality, the main processor 1800 of the cleaner body 1000 may store details of the abnormality in the memory 1900, or may output a failure notification and then turn off the power.

In operation S1540, when there is no abnormality (normal state) in the vacuum cleaner, the vacuum cleaner according to an embodiment of the disclosure may obtain a voltage value input through the moisture detection circuit 1135. For example, when there is no product abnormality, the main processor 1800 of the cleaner body 1000 may request the first processor 1131 for information about whether there is moisture ingress into the first processor 1131. In this case, the first processor 1131 may obtain a voltage value input to an input port of the first processor 1131 through the moisture detection circuit 1135.

In operation S1550, the vacuum cleaner according to an embodiment of the disclosure may determine whether the voltage value input through the moisture detection circuit 1135 is equal to or greater than a first reference voltage value. The first reference voltage value may be a minimum voltage value for detecting a liquid. The first reference voltage value may be a voltage value based on the resistance of a liquid (e.g., pure water) not affecting component burnout or insulation tracking. For example, the first reference voltage value may be, but is not limited to, 0.5 V.

In operation S1560, when the voltage value input through the moisture detection circuit 1135 is less than the first reference voltage value (No in operation S1550), the vacuum cleaner according to an embodiment of the disclosure may determine that there is no moisture (liquid) in the cleaner body 1000 and may drive the suction motor 1110.

For example, when the voltage value input through the moisture detection circuit 1135 is less than the first reference voltage value, the first processor 1131 may determine that there is no moisture (liquid) in the cleaner body 1000. Then, the first processor 1131 may transmit data indicating that there is no moisture in the cleaner body 1000 to the main processor 1800. In this case, the main processor 1800 may transmit a signal indicating to drive the suction motor 1110 to the first processor 1131. The main processor 1800 may transmit information about a suction power mode set by a user to the first processor 1131. The first processor 1131 may drive the suction motor 1110 according to a signal received from the suction motor 1110. Also, the first processor 1131 may change a suction power strength (power consumption of the suction motor 1110 and RPM of the suction motor 1110) according to the suction power mode set by the user.

In operation S1570, when the voltage value input through the moisture detection circuit 1135 is equal to or greater than the first reference voltage value (Yes in operation S1550), the vacuum cleaner according to an embodiment of the disclosure may compare the voltage value input through the moisture detection circuit 1135 with a second reference voltage value.

The second reference voltage value may be greater than the first reference voltage value. The second reference voltage value may be a voltage value based on the resistance of a reference liquid affecting component burnout or insulation tracking. The second reference voltage value may vary according to a moisture detection sensitivity. For example, when the moisture detection sensitivity is set low, the second reference voltage value may increase, and when the moisture detection sensitivity is set high, the second reference voltage value may decrease. Also, when the reference liquid is a liquid having a high electrical conductivity (e.g., seawater), the second reference voltage value may increase, and when the reference liquid is a liquid having a low electrical sensitivity (e.g., tap water), the second reference voltage value may decrease.

In operation S1580, when the voltage value input through the moisture detection circuit 1135 is equal to or greater than the second reference voltage value (Yes in operation S1570), the vacuum cleaner according to an embodiment of the disclosure may deactivate driving of the suction motor 1110.

For example, when the voltage value input through the moisture detection circuit 1135 is equal to or greater than the second reference voltage value, the first processor 1131 may determine that there is moisture (liquid) affecting component burnout or insulation tracking in the cleaner body 1000. The first processor 1131 may transmit data indicating that there is moisture affecting component burnout or insulation tracking in the cleaner body 1000 to the main processor 1800. In this case, the main processor 1800 may transmit a signal indicating to deactivate driving of the suction motor 1110 to the first processor 1131. The first processor 1131 may not drive the suction motor 1110 according to the signal received from the suction motor 1110, thereby effectively preventing fire caused by component burnout or insulation tracking.

The main processor 1800 may store, in the memory 1900, information indicating that a liquid has been detected in the PCB 1130 for controlling the suction motor 1110 and may turn off the power of the vacuum cleaner. The main processor 1800 may output, to a display or may transmit to a server device, information indicating that a liquid has been detected in the PCB 1130 for controlling the suction motor 1110 before turning off the power of the vacuum cleaner. When the main processor 1800 transmits information indicating that a liquid has been detected to the server device, the user may execute an application in a user terminal connected to the server device to check that the power of the vacuum cleaner has been turned off due to liquid detection.

In operation S1590, when the voltage value input through the moisture detection circuit 1135 is equal to or greater than the first reference voltage value but less than the second reference voltage value (No in operation S1570), the vacuum cleaner according to an embodiment of the disclosure may calibrate the first reference voltage value.

For example, when the vacuum cleaner is used in a humid area or under a special condition (e.g., a basement), the voltage value input through the moisture detection circuit 1135 may be between the first reference voltage value and the second reference voltage value. Accordingly, even when there is no moisture affecting component burnout or insulation tracking in the cleaner body 1000, the vacuum cleaner should unnecessarily perform an additional operation of comparing the voltage value input to the input port with the second reference voltage value. In order to prevent the operation of comparing the voltage value input to the input port with the second reference voltage value from being unnecessarily performed, the vacuum cleaner may adjust the first reference voltage value to a value higher than the current value. In this case, the vacuum cleaner may gradually adjust the first reference voltage value step by step, rather than rapidly increasing the first reference voltage value.

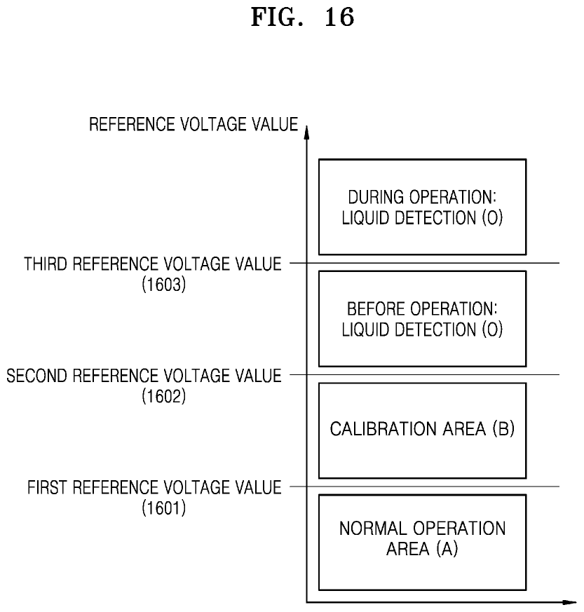

The vacuum cleaner may turn off the power after calibrating the first reference voltage value. Hereinafter, an operation in which a vacuum cleaner calibrates a first reference value will be described in more detail with reference to FIG. 16.

FIG. 16 is a diagram for describing reference voltage values, according to an embodiment of the disclosure.

A first reference voltage value 1601 and a second reference voltage value 1602 may be reference values for determining whether there is moisture in the cleaner body 1000 before driving of the suction motor 1110, and a third reference voltage value 1603 may be a reference value for determining whether moisture has been introduced into the cleaner body 1000 during driving of the suction motor 1110.

The first reference voltage value 1601 may be a voltage value based on the resistance of a liquid (e.g., pure water) not affecting component burnout or insulation tracking. The second reference voltage value 1602 and the third reference voltage value 1603 may be voltage values based on the resistance of a reference liquid affecting component burnout or insulation tracking. The second reference voltage value 1602 and the third reference voltage value 1603 may be the same as each other, or the third reference voltage value 1603 may be greater than the second reference voltage value 1602.

Accordingly, when a voltage value input to an input port of the first processor 1131 is less than the first reference voltage value 1601, a vacuum cleaner may normally drive the suction motor 1110 by determining that there is no moisture in the cleaner body 1000, and when a voltage value input to the input port of the first processor 1131 is equal to or greater than the second reference voltage value 1602, the vacuum cleaner may deactivate driving of the suction motor 1110 by determining that there is moisture affecting component burnout or insulation tracking in the cleaner body 1000. For example, because general water (e.g., tap water, purifier water, or slight dirt) is unlikely to lead to circuit failure (burnout) unless the general water is large, the suction motor 1110 may be normally driven even when there is the general water in the cleaner body. However, when there is salt water or dog urine, which may lead to circuit burnout, in the cleaner body 100, driving of the suction motor 1110 may be deactivated.

When a voltage value input to the input port of the first processor 1131 is equal to or greater than the first reference voltage value 1601 but less than the second reference voltage value 1602, the vacuum cleaner may determine that there is a small amount of moisture in the cleaner body 1000 which does not affect component burnout or insulation tracking. That is, because a probability that a voltage input to the input port of the first processor 1131 is between the first reference voltage value 1601 and the second reference voltage value 1602 increases in a humid area or under a special condition (e.g., a basement), the vacuum cleaner may adjust the first reference voltage value to a value higher than the current value so that a voltage value input to the input port of the first processor 1131 is less than the first reference voltage value 1601. When a voltage value input to the input port of the first processor 1131 is less than the first reference voltage value 1601, the vacuum cleaner may omit an operation of comparing a voltage value input to the input port of the first processor 1131 with the second reference voltage, thereby reducing battery consumption.

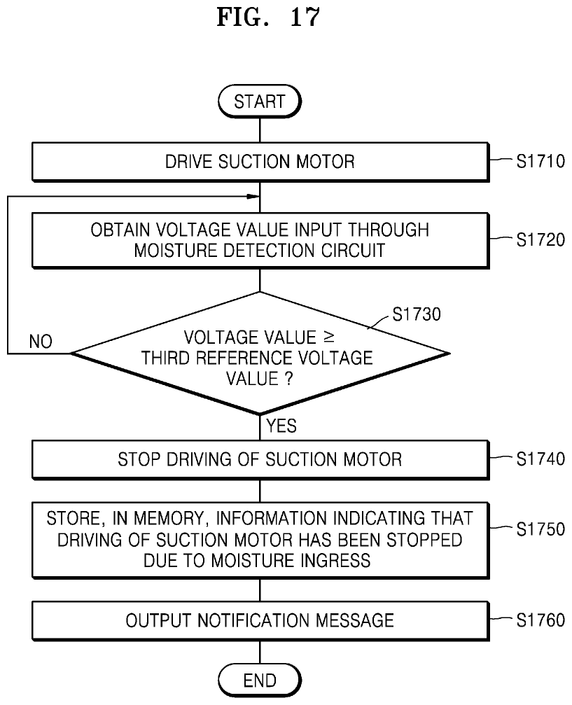

When a voltage value input to the input port of the first processor 1131 during driving of the suction motor 1110 is equal to or greater than the third reference voltage value 1603, the vacuum cleaner may determine that a liquid affecting component burnout or insulation tracking has been introduced into the cleaner body 1000 and may stop driving of the suction motor 1110. Hereinafter, a method by which a vacuum cleaner detects moisture ingress during driving of the suction motor 1110 and stops driving of the suction motor 1110 will be described in detail with reference to FIG. 17.

FIG. 17 is a flowchart for describing a method of detecting moisture ingress during driving of the suction motor 1110, according to an embodiment of the disclosure.

In operation S1710, a vacuum cleaner according to an embodiment of the disclosure may drive the suction motor 1110.

Operation S1710 may correspond to operation S1560 of FIG. 15. For example, when there is no abnormality in the vacuum cleaner as a result of checking for a product abnormality and a voltage value input to an input port of the first processor 1131 is less than the first reference voltage value 1601, the vacuum cleaner may drive the suction motor 1110 because there is no moisture in the cleaner body 1000.

In operation S1720, the vacuum cleaner according to an embodiment of the disclosure may obtain a voltage value input through the moisture detection circuit 1135 during driving of the suction motor 1110.

When the suction motor 1110 operates, the main processor 1800 may periodically check whether a liquid is detected in the PCB 1130 for controlling the suction motor 1110 by periodically communicating with the first processor 1131. Accordingly, the first processor 1131 may monitor a voltage value input through the moisture detection circuit 1135 during driving of the suction motor 1110.

In operation S1730, the vacuum cleaner according to an embodiment of the disclosure may compare the voltage value input to the input port through the moisture detection circuit 1135 with the third reference voltage value 1603. For example, the first processor 1131 may compare the voltage value input to the input port with the third reference voltage value 1603 that is preset.

The third reference voltage value 1603 may be a voltage value based on the resistance of a reference liquid affecting component burnout or insulation tracking. The third reference voltage value 1603 may be the same as the second reference voltage value 1602 or may be greater than the second reference voltage value 1602. In an embodiment, the third reference voltage value 1603 may be less than the second reference voltage value 1602.

When the voltage value input to the input port through the moisture detection circuit 1135 is less than the third reference voltage value 1603 (No in operation S1730), the first processor 1131 according to an embodiment of the disclosure may determine that moisture has not been introduced into the cleaner body 1000 and may continue to monitor a voltage value input through the moisture detection circuit 1135.

In operation S1740, when the voltage value input to the input port through the moisture detection circuit 1135 is equal to or greater than the third reference voltage value 1603 (Yes in operation S1730), the vacuum cleaner according to an embodiment of the disclosure may stop driving of the suction motor 1110.

In operation S1750, the vacuum cleaner according to an embodiment of the disclosure may store, in the memory 1900, information indicating that driving of the suction motor 1110 has been stopped due to moisture ingress.

In operation S1760, the vacuum cleaner according to an embodiment of the disclosure may output a notification message indicating that moisture has been introduced into the cleaner body 1000.

Operations S1740 to S1760 correspond to operations S630 to S650 of FIG. 6, and thus, any repetitive detailed description thereof will be omitted. According to an embodiment of the disclosure, operation S1750 or operation S1760 may be omitted.

According to an embodiment of the disclosure, because the vacuum cleaner stops driving of the suction motor 1110 when it is detected that a liquid has been introduced into the cleaner body 1000 through the moisture detection circuit during driving of the suction motor 1110, fire caused by component burnout or insulation tracking may be effectively prevented.

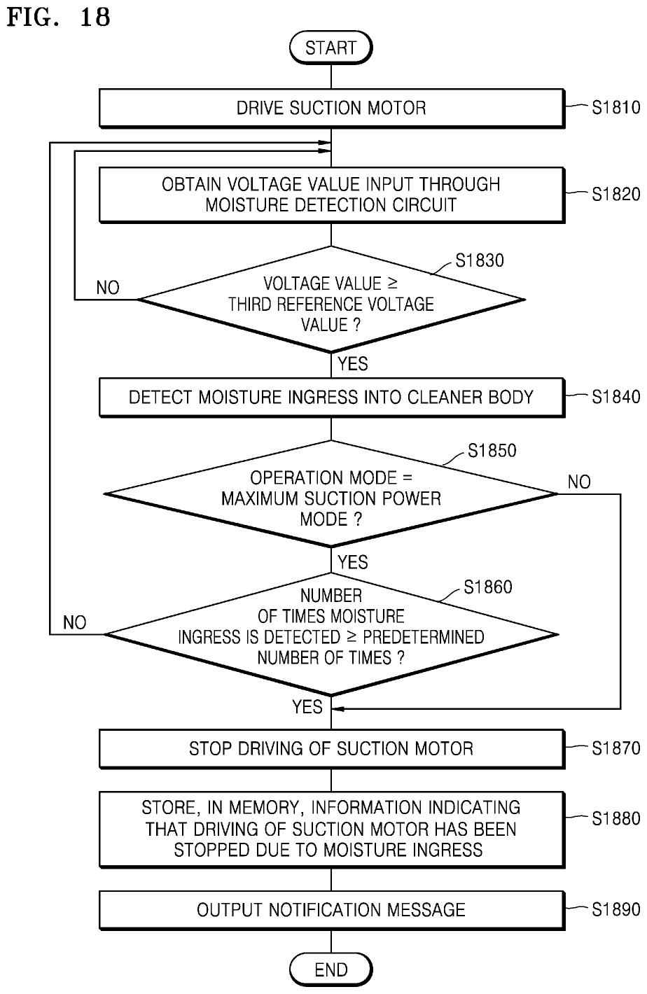

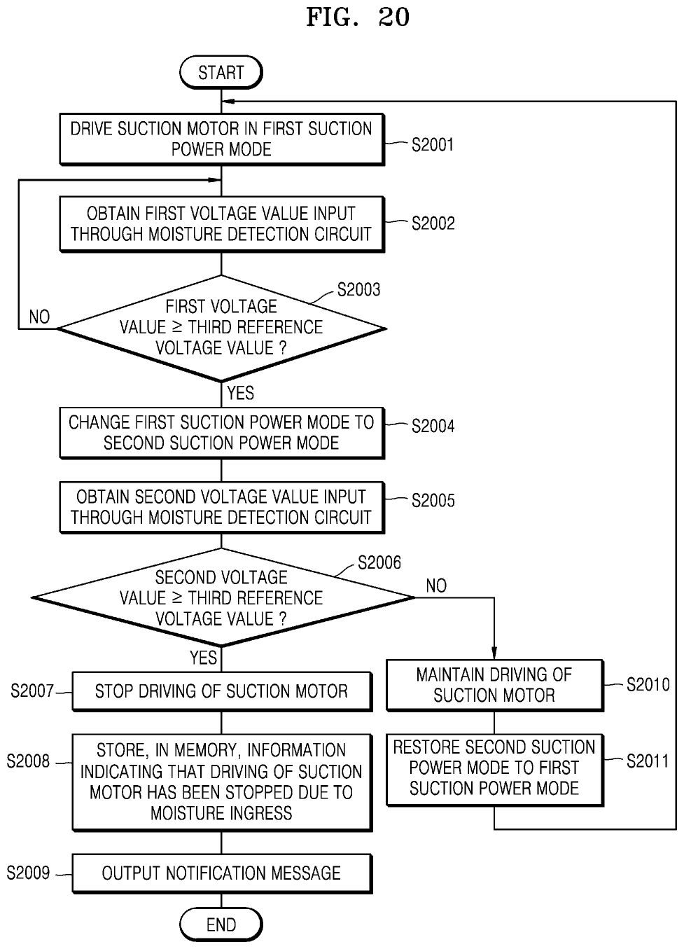

In case where the vacuum cleaner operates in a maximum suction power mode, even when there is a very small amount of liquid on a surface to be cleaned which does not affect the vacuum cleaner, moisture ingress may be detected and thus driving of the suction motor 1110 may be stopped. Accordingly, a method of preventing driving of the suction motor 1110 from being unnecessarily stopped in a maximum suction power mode will be described in detail with reference to FIGS. 18 and 20.

FIG. 18 is a flowchart for describing a method of detecting moisture ingress in a maximum suction power mode, according to an embodiment of the disclosure.

In operation S1810, a vacuum cleaner according to an embodiment of the disclosure may drive the suction motor 1110.

Operation S1810 may correspond to operation S1560 of FIG. 15. For example, when there is no abnormality in the vacuum cleaner as a result of checking for a product abnormality and a voltage value input to an input port of the first processor 1131 is less than the first reference voltage value 1601, the vacuum cleaner may drive the suction motor 1110 because there is no moisture in the cleaner body 1000.

In operation S1820, the vacuum cleaner according to an embodiment of the disclosure may obtain a voltage value input through the moisture detection circuit 1135.

For example, when the suction motor 1110 operates, the main processor 1800 may periodically check whether a liquid is detected in the PCB 1130 for controlling the suction motor 1110 by periodically communicating with the first processor 1131. Accordingly, the first processor 1131 may monitor a voltage value input through the moisture detection circuit 1135 during driving of the suction motor 1110.

In operation S1830, the vacuum cleaner according to an embodiment of the disclosure may compare the voltage value input through the moisture detection circuit 1135 with the third reference voltage value 1603. For example, the first processor 1131 may compare the voltage value input to the input port with the third reference voltage value 1603 that is preset.

When the voltage value input to the input port through the moisture detection circuit 1135 is less than the third reference voltage value 1603 (No in operation S1830), the first processor 1131 according to an embodiment of the disclosure may determine that moisture has not been introduced into the cleaner body 1000 and may continue to monitor a voltage value input through the moisture detection circuit 1135.

In operation S1840, when the voltage value input to the input port through the moisture detection circuit 1135 is equal to or greater than the third reference voltage value 1603 (Yes in operation S1830), the vacuum cleaner according to an embodiment of the disclosure may detect moisture ingress into the cleaner body 1000.

In operation S1850, when the vacuum cleaner according to an embodiment of the disclosure detects moisture ingress into the cleaner body 1000, the vacuum cleaner may determine whether an operation mode is a maximum suction power mode.

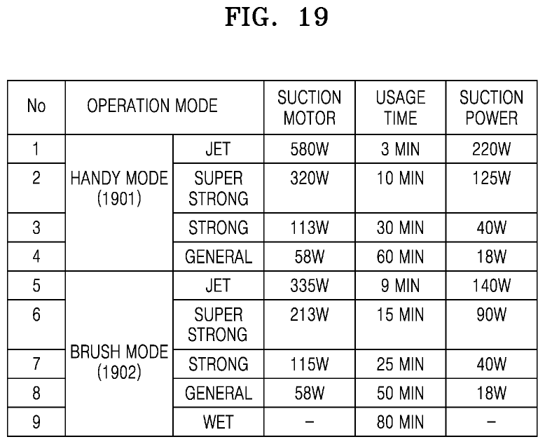

Referring to FIG. 19, an operation mode of a vacuum cleaner may include a handy mode 1901 and a brush mode 1902. The handy mode 1901 may be a mode in which the brush device 2000 is not coupled to the cleaner body 1000, and the brush mode 1902 may be a mode in which the brush device 2000 is coupled to the cleaner body 1000. The handy mode 1901 may be divided into a jet mode, a super strong mode, a strong mode, and a general mode according to suction power. The brush mode 1902 may also be divided into a jet mode, a super strong mode, a strong mode, and a general mode according to suction power. A maximum suction power mode in the handy mode 1901 may be the jet mode, and a maximum suction power mode in the brush mode 1902 may be the jet mode.

According to an embodiment of the disclosure, when moisture ingress into the cleaner body 1000 is detected and the operation mode is not the maximum suction power mode (No in operation S1850), at least one processor 1010 of the vacuum cleaner according to an embodiment of the disclosure may stop driving of the suction motor 1110. That is, when moisture ingress into the cleaner body 1000 is detected in a low suction power mode, there may be a considerable amount of liquid on a surface to be cleaned, and thus, the at least one processor 1010 of the vacuum cleaner may immediately stop driving of the suction motor 1110.

In operation S1860, when moisture ingress into the cleaner body 1000 is detected and the operation mode is the maximum suction power mode (Yes in operation S1860), the vacuum cleaner according to an embodiment of the disclosure may determine whether the number of times moisture ingress is detected is equal to or greater than a predetermined number of times. The predetermined number of times may be 2, or 3 or more.

For example, when the predetermined number of times is 2, the vacuum cleaner may determine whether the number of times moisture ingress is detected by the first processor 1131 is 2 or more.

According to an embodiment of the disclosure, when the number of times moisture ingress is detected is less than the predetermined number of times (No in operation S1860), the vacuum cleaner may detect moisture ingress once again through the moisture detection circuit 1135. In this case, when moisture ingress is not detected again, the vacuum cleaner may maintain driving of the suction motor 1110.

In operation S1870, when the operation mode is the maximum suction power mode (Yes in operation S1850) and the number of times moisture ingress is detected is equal to or greater than the predetermined number of times (Yes in operation S1860), the vacuum cleaner may stop driving of the suction motor 1110.

According to an embodiment of the disclosure, when the number of times moisture ingress is detected is equal to or greater than the predetermined number of times in the maximum suction power mode, a probability that there is a large amount of liquid on the surface to be cleaned is high, and thus, the vacuum cleaner may stop driving of the suction motor 1110 to prevent fire caused by component burnout or insulation tracking.

In operation S1880, when driving of the suction motor 1110 has been stopped, the vacuum cleaner according to an embodiment of the disclosure may store, in the memory 1900, information indicating that driving of the suction motor has been stopped due to moisture ingress.

In operation S1890, when driving of the suction motor 1110 has been stopped, the vacuum cleaner according to an embodiment of the disclosure may visually or audibly output a notification message indicating that moisture has been introduced into the cleaner body 1000.

Operations S1880 to S1890 correspond to operations S630 to S650 of FIG. 6, and thus, any repetitive detailed description thereof will be omitted. According to an embodiment of the disclosure, operation S1880 or operation S1890 may be omitted.

According to an embodiment of the disclosure, in a case where suction power of the cleaner body 1000 is strong, even when there is a small amount of liquid on the surface to be cleaned, moisture ingress may be detected by the first processor 1131 and driving of the suction motor 1110 may be stopped. Accordingly, when suction power of the cleaner body 1000 is strong, driving of the suction motor 1110 may be effectively prevented from being unnecessarily frequently stopped by stopping driving of the suction motor 1110 only when moisture ingress is detected only the predetermined number of times or more.

FIG. 20 is a flowchart for describing a method of changing a suction power mode according to moisture ingress, according to an embodiment of the disclosure.

In operation S2001, a vacuum cleaner according to an embodiment of the disclosure may drive the suction motor 1110 in a first suction power mode.

For example, when a user turns on the power of the vacuum cleaner, the main processor 1800 of the cleaner body 1000 may detect an abnormality of cleaner components (e.g., the battery module 1500, the suction motor 1110, the brush device 2000, and the pressure sensor 1400), and may drive the suction motor 1110 in the first suction power mode when there is no abnormality in the cleaner components. The first suction power mode may be a default mode, or may be a mode selected by the user.

In operation S2002, the vacuum cleaner according to an embodiment of the disclosure may obtain a first voltage value input through the moisture detection circuit 1135 during driving of the suction motor 1110 in the first suction power mode.

For example, when the suction motor 1110 operates, the main processor 1800 may periodically check whether a liquid is detected in the PCB 1130 for controlling the suction motor 1110 by periodically communicating with the first processor 1131. Accordingly, the first processor 1131 may monitor a voltage value input through the moisture detection circuit 1135 during driving of the suction motor 1110.

In operation S2003, the vacuum cleaner according to an embodiment of the disclosure may compare the first voltage value input through the moisture detection circuit 1135 with the third reference voltage value 1603. For example, the first processor 1131 may compare a voltage value input to an input port with the third reference voltage value 1603 that is preset.

When the first voltage value input to the input port through the moisture detection circuit 1135 is less than the third reference voltage value 1603 (No in operation S2003), the first processor 1131 according to an embodiment of the disclosure may determine that moisture has not been introduced into the cleaner body 1000 and may continue to monitor the first voltage value input through the moisture detection circuit 1135.

In operation S2004, when the first voltage value input through the moisture detection circuit 1135 is equal to or greater than the third reference voltage value (Yes in operation S2003), the vacuum cleaner according to an embodiment of the disclosure may change the first suction power mode to a second suction power mode. The second suction power mode may be a mode with a suction power strength lower than that of the first suction power mode.

When the first voltage value input through the moisture detection circuit 1135 is equal to or greater than the third reference voltage value (Yes in operation S2003), the vacuum cleaner may determine that moisture has been introduced into the cleaner body 1000. However, because suction power in the first suction power mode may be so strong that a liquid on a surface to be cleaned reaches the moisture detection circuit 1135, the vacuum cleaner may lower the suction power mode by one step, or two or more steps.

According to an embodiment of the disclosure, when the first suction power mode is a minimum suction power mode, because the vacuum cleaner may no longer reduce suction power, the vacuum cleaner may immediately stop driving of the suction motor 1110.

In operation S2005, the vacuum cleaner according to an embodiment of the disclosure may obtain a second voltage value input through the moisture detection circuit 1135 while driving the suction motor 1110 in the second suction power mode with a suction power strength lower than that of the first suction power mode. For example, in a case where the first suction power mode is a jet mode, the vacuum cleaner may obtain the second voltage value input through the moisture detection circuit 1135 while driving the suction motor 1110 in a super strong mode with a suction power strength that is lower by one step than that of the jet mode.

In operation S2006, the vacuum cleaner according to an embodiment of the disclosure may compare the second voltage value input through the moisture detection circuit 1135 in the second suction power mode with the third reference voltage value 1603.

In operation S2007, when the second voltage value input through the moisture detection circuit 1135 in the second suction power mode is equal to or greater than the third reference voltage value 1603 (Yes in operation S2006), the vacuum cleaner according to an embodiment of the disclosure may stop driving of the suction motor 1110.

According to an embodiment of the disclosure, when the second voltage value is equal to or greater than the third reference voltage value 1603 (Yes in operation S2006), the vacuum cleaner may determine that moisture has been introduced even in the second suction power mode with a suction power strength lower than that of the first suction power mode. Accordingly, the vacuum cleaner may immediately stop driving of the suction motor 1110 to effectively prevent fire caused by component burnout or insulation tracking.

In operation S2008, after stopping driving of the suction motor 1110, the vacuum cleaner according to an embodiment of the disclosure may store, in the memory 1900, information indicating that driving of the suction motor 1110 has been stopped due to moisture ingress.

In operation S2009, when driving of the suction motor 1110 has been stopped, the vacuum cleaner according to an embodiment of the disclosure may visually or audibly output a notification message indicating that moisture has been introduced into the cleaner body 1000.

Operations S2008 to S2009 correspond to operations S630 to S650 of FIG. 6, and thus, any repetitive detailed description thereof will be omitted. According to an embodiment of the disclosure, operation S2008 or operation S2009 may be omitted.

In operation S2010, when the second voltage value input through the moisture detection circuit 1135 in the second suction power mode is less than the third reference voltage value 1603 (Yes in operation S2006), the vacuum cleaner according to an embodiment of the disclosure may maintain driving of the suction motor 1110.

For example, when the operation mode changes to the second suction power mode with a suction power strength lower than that of the firs suction power mode and moisture is no longer introduced into the cleaner body 1000, there is no effect on component burnout or insulation tracking, and thus, the vacuum cleaner may maintain driving of the suction motor 1110.

In operation S2011, the vacuum cleaner according to an embodiment of the disclosure may restore the second suction power mode to the first suction power mode.

According to an embodiment of the disclosure, when moisture ingress is not detected in the second suction power mode, the vacuum cleaner may change the second suction power mode back to the first suction power mode. Alternatively, when a certain period of time (e.g., 1 minute) has elapsed after the operation mode changes to the second suction power mode, the vacuum cleaner may change the second suction power mode to the first suction power mode. In this case, the vacuum cleaner may continue to monitor whether there is moisture ingress into the cleaner body 1000 while driving the suction motor 1110.

According to an embodiment of the disclosure, in order to prevent driving of the suction motor 1110 from being frequently stopped due to introduction of a small amount of moisture into the moisture detection circuit 1135 due to strong suction power, the vacuum cleaner may adaptively lower suction power. When moisture is not introduced into the cleaner body 1000 in a state where suction power is lowered, the vacuum cleaner may maintain driving of the suction motor 1110.

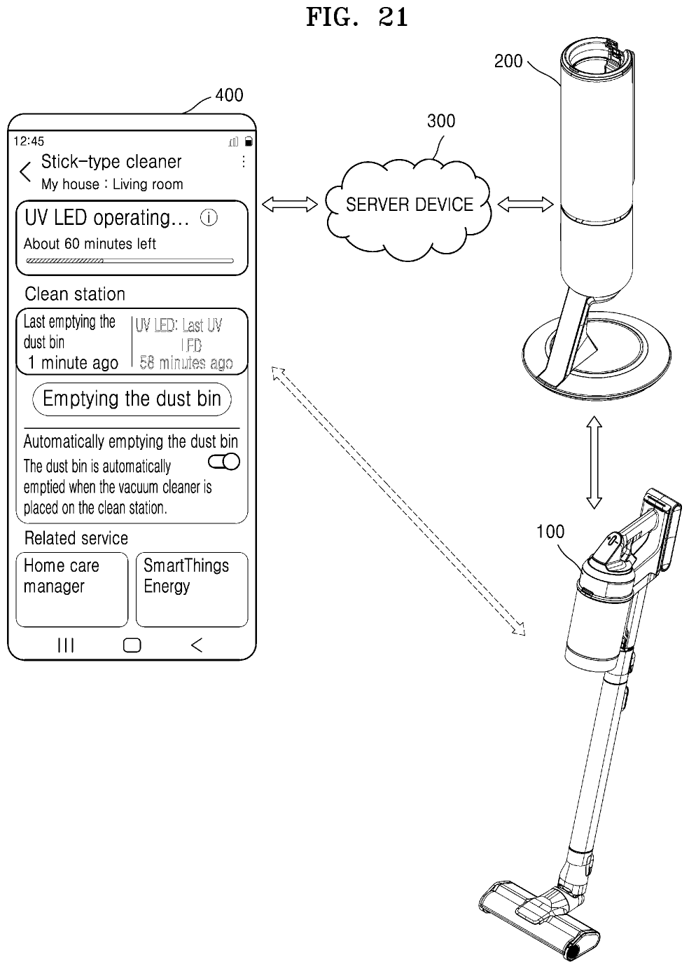

FIG. 21 is a view for describing a cleaning system, according to an embodiment of the disclosure.

Referring to FIG. 21, a cleaning system according to an embodiment of the disclosure may include a vacuum cleaner, a station device 200, a server device 300, and a user terminal 400. In FIG. 21, an embodiment where vacuum cleaner is a cordless vacuum cleaner 100 will be described as an example.

The station device 200 may be a device for discharging dust, charging a battery, or storing the cordless vacuum cleaner 100. The station device 200 may be referred to as a clean station or a charging station. According to an embodiment of the disclosure, the station device 200 may communicate with the cordless vacuum cleaner 100 or the server device 300 through a network. For example, the station device 200 may transmit and receive data to and from the cordless vacuum cleaner 100 through a short-range wireless network (wireless personal area network (WPAN)) without an access point (AP).

The station device 200 may transmit and receive data to and from the server device 300 through an AP that connects a local area network (LAN) to which the station device 200 is connected to a wide area network (WAN) to which the server device 300 is connected.

For example, the station device 200 may be connected to the cordless vacuum cleaner 100 through Bluetooth low energy (BLE) communication, and may be connected to the server device 300 through Wi-Fi™ (IEEE 802.11) communication, but an embodiment of the disclosure is not limited thereto.

According to an embodiment of the disclosure, the station device 200 may include, but is not limited to, a communication interface, at least one processor, a suction motor (hereinafter, referred to as a second suction motor), and a collector. The second suction motor may be a device configured to generate suction power for discharging foreign materials collected in the dust bin 1200 of the cordless vacuum cleaner 100 from the cordless vacuum cleaner 100. For example, the second suction motor may generate a pressure difference inside the dust bin 1200. The second suction motor may be located below the collector when the station device 200 is erected.

The server device 300 according to an embodiment of the disclosure may be a device for managing the station device 200 and the cordless vacuum cleaner 100. For example, the server device 300 may be a home appliance management server. The server device 300 may manage user account information and information about a home appliance connected to a user account. For example, a user may create a user account by accessing the server device 300 through the user terminal 400. The user account may be identified by an ID and a password set by the user. The server device 300 may register the station device 200 and the cordless vacuum cleaner 100 in the user account according to a given procedure. For example, the server device 300 may register the station device 200 and the cordless vacuum cleaner 100 by connecting identification information (e.g., a serial number or a MAC address) of the station device 200 and identification information of the cordless vacuum cleaner 100 to the user account. When the station device 200 and the cordless vacuum cleaner 100 are registered in the server device 300, the server device 300 may manage a state of the station device 200 or a state of the cordless vacuum cleaner 100 by periodically receiving state information of the station device 200 or state information of the cordless vacuum cleaner 100 from the station device 200.

The user terminal 400 may be a device registered in the server device 300 with the same account as the station device 200 or the cordless vacuum cleaner 100. Examples of the user terminal 400 may include, but are not limited to, a smartphone, a laptop computer, a tablet personal computer (PC), a digital camera, an e-book terminal, a digital broadcasting terminal, a personal digital assistant (PDA), a portable multimedia player (PMP), a wearable device, and a device including a display. For convenience of description, embodiments where the user terminal 400 is a smartphone will hereinafter be described.

According to an embodiment of the disclosure, the user terminal 400 may communicate with at least one of the server device 300, the station device 200, or the cordless vacuum cleaner 100. The user terminal 400 may directly communicate with the station device 200 or the cordless vacuum cleaner 100 through short-range wireless communication, or may indirectly communicate with the station device 200 or the cordless vacuum cleaner 100 through the server device 300.

According to an embodiment of the disclosure, the user terminal 400 may execute a specific application (e.g., a home appliance management application) provided by the server device 300, based on a user input. In this case, the user may check a state of the cordless vacuum cleaner 100 or a state of the station device 200 through an execution window of the application. For example, the user terminal 400 may provide, through the execution window of the application, information related to an operation of an ultraviolet irradiator (e.g., “UV LED is operating”) and information related to dust discharge (e.g., “last emptying the dust bin−1 minute ago”) of the station device 200, but an embodiment of the disclosure is not limited thereto.

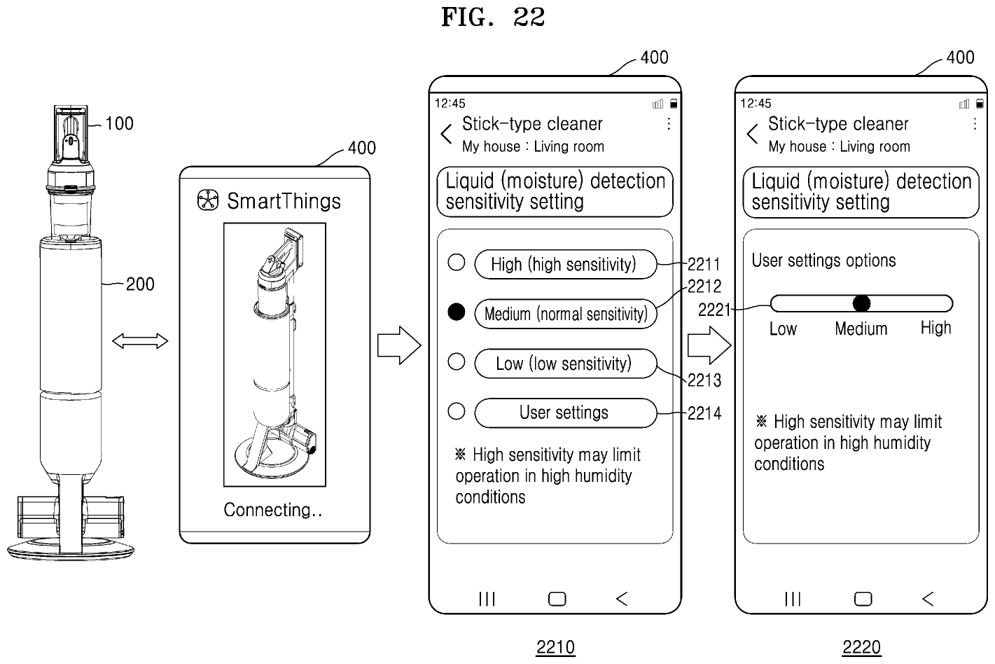

The user terminal 400 may provide an icon related to dust discharge (e.g., “emptying the dust bin”), a graphical user interface (GUI) for setting a discharge mode (e.g., a manual discharge mode, an automatic discharge mode, or a smart discharge mode button), a GUI for setting a critical drop amount for a smart discharge mode, a GUI for setting a discharge strength or a discharge duration, and a GUI for setting a discharge timing condition. Also, the user terminal 400 may provide a GUI for setting a moisture detection sensitivity. A GUI for setting a moisture detection sensitivity will be described in more detail with reference to FIG. 22.

FIG. 22 is a view for describing an example of a GUI for setting a moisture detection sensitivity, according to an embodiment of the disclosure.

Referring to FIG. 22, a user may set a moisture detection sensitivity through the user terminal 400. For example, the user terminal 400 may display a first screen 2210 of a certain application (e.g., a home appliance management application). The first screen 2210 may include icons for setting a moisture detection sensitivity. For example, the first screen 2210 may include a first icon 2211 for setting a moisture detection sensitivity to high, a second icon 2212 for setting a moisture detection sensitivity to medium, a third icon 2213 for setting a moisture detection sensitivity to low, and a fourth icon 2214 for finely adjusting a moisture detection sensitivity.

When the user selects one of the first icon 2211, the second icon 2212, and the third icon 2213, the user terminal 400 may transmit information about a moisture detection sensitivity corresponding to the selected icon to the station device 200. In this case, the user terminal 400 may transmit the information about the moisture detection sensitivity corresponding to the selected icon to the station device 200 via the server device 300. For example, when the user terminal 400 selects a user input that selects the second icon 2212, the user terminal 400 may transmit information indicating that a user input that selects a moisture detection sensitivity to medium has been received to the server device 300. The server device 300 may transmit information indicating to set a moisture detection sensitivity to medium to the station device 200. In this case, the station device 200 may transmit information indicating to set a moisture detection sensitivity to medium to the cordless vacuum cleaner 100 through short-range wireless communication (e.g., BLE communication). In an embodiment, the user terminal 400 may transmit information indicating to set a moisture detection sensitivity to medium to the station device 200 through short-range wireless communication to the station device 200 without passing through the server device 300. Also, the user terminal 400 may transmit information indicating to set a moisture detection sensitivity to medium to the cordless vacuum cleaner 100 without passing through the server device 300 and the station device 200.

When information about a moisture detection sensitivity set by the user is received, the cordless vacuum cleaner 100 may adjust a reference voltage value for determining liquid ingress into the cleaner body 1000. For example, when a moisture detection sensitivity is set low, the cordless vacuum cleaner 100 may adjust a reference voltage value to be higher, and when a moisture detection sensitivity is set high, the cordless vacuum cleaner 100 may adjust a reference voltage value to be lower.

When the user selects the fourth icon 2214 for finely adjusting a moisture detection sensitivity on the first screen 2210, the user terminal 400 may display a second screen 2220. A GUI 2221 (e.g., a bar) for finely adjusting a moisture detection sensitivity may be displayed on the second screen 2220. The user may finely adjust a moisture detection sensitivity through the GUI 2221. For example, the user may lower a moisture detection sensitivity so that the cordless vacuum cleaner 100 detects introduction of a liquid having an electrical conductivity equal to or higher than an electrical conductivity of seawater which causes circuit failure, or may increase a moisture detection sensitivity so that the cordless vacuum cleaner 100 detects all liquids having an electrical conductivity equal to or higher than an electrical conductivity of pure water. When a moisture detection sensitivity is set high, a probability that the suction motor 1110 frequently stopped may increase.

According to an embodiment of the disclosure, the cordless vacuum cleaner 100 may operate in conjunction with the user terminal 400 to output a notification related to moisture ingress from the user terminal 400. Hereinafter, an operation in which the user terminal 400 outputs a notification related to moisture ingress will be described in detail with reference to FIG. 23.

FIG. 23 is a view for describing an operation in which the user terminal 400 outputs a notification, according to an embodiment of the disclosure.

According to an embodiment of the disclosure, when the cordless vacuum cleaner 100 detects that moisture has been introduced into the cleaner body 1000, the cordless vacuum cleaner 100 may stop driving of the suction motor 1110, and may enable the user terminal 400 connected through the server device 300 to output a notification message indicating that moisture has been introduced into the cleaner body 1000.

For example, the cordless vacuum cleaner 100 may transmit information indicating that moisture has been introduced into the cleaner body 1000 to the server device 300. In this case, the cordless vacuum cleaner 100 may transmit the information to the server device 300 through the station device 200, or may directly transmit the information to the server device 300 without passing through the station device 200.

The server device 300, when receiving the information indicating that moisture has been introduced into the cleaner body 1000, may transmit information indicating that moisture has been introduced into the cleaner body 1000 to the user terminal 400 through a specific application (e.g., a home appliance management application) installed in the user terminal 400. The user terminal 400 may output a notification message 2301 indicating that moisture has been introduced into the cleaner body 1000 on an execution window of the application. For example, the user terminal 400 may output the notification message 2301 saying “Liquid ingress into the cleaner body!! Please use it later”.

When an operation of the cordless vacuum cleaner 100 is stopped during cleaning, a user may check that moisture has been introduced into the cordless vacuum cleaner 100 through the notification message 2301 of the user terminal 400.

The vacuum cleaner according to an embodiment of the disclosure may include: the battery module 1500 configured to supply power to the cleaner body 1000; the motor assembly 1100 including the PCB 1130, the suction motor 1110, and the impeller 1120 arranged in this order along a direction of a flow path in the cleaner body 1000; the moisture detection circuit 1135 provided on the PCB 1130 of the motor assembly 1100 and configured to detect moisture introduced thereinto through the flow path; and at least one processor 1010 configured to stop driving of the suction motor 1110 when it is determined that moisture has been introduced into the cleaner body 1000 through the moisture detection circuit 1135.

The moisture detection circuit 1135 according to an embodiment of the disclosure may be located between the positive (+) terminal 501 and the negative (−) terminal 502 of the PCB 1130, which electrically connect the motor assembly 1100 to the battery module 1500.

The moisture detection circuit 1135 according to an embodiment of the disclosure may be connected to an input port of the first processor 1131 of the motor assembly 1100 including the PCB 1130 and a positive (+) power line which receives power from the battery module 1500.

The at least one processor 1010 according to an embodiment of the disclosure may include at least one of the main processor 1800 of the cleaner body 1000 or the first processor 1131 of the motor assembly 1100. When the first processor 1131 of the motor assembly 1100 according to an embodiment of the disclosure identifies that moisture has been introduced into the cleaner body 1000 through the moisture detection circuit 1135, the first processor 1131 may transmit information indicating that moisture has been introduced into the cleaner body 1000 to the main processor 1800. The first processor 1131 of the motor assembly 1100 may receive a signal indicating to stop driving of the suction motor 1110 from the main processor 1800.

The at least one processor 1010 according to an embodiment of the disclosure may determine whether moisture has been introduced into the cleaner body 1000 by comparing a voltage value input through the moisture detection circuit 1135 with a reference voltage value.

The at least one processor 1010 according to an embodiment of the disclosure may stop driving of the suction motor 1110 when the voltage value input through the moisture detection circuit 1135 is equal to or greater than the reference voltage value.

The reference voltage value according to an embodiment of the disclosure may be predefined based on a resistance value corresponding to an electrical conductivity of urine of a companion animal.

According to an embodiment of the disclosure, the voltage value input to the at least one processor 1010 through the moisture detection circuit 1135 may vary based on an electrical conductivity of moisture introduced into the cleaner body 1000.

The moisture detection circuit 1135 according to an embodiment of the disclosure may include the first moisture detection circuit 1135-1 and the second moisture detection circuit 1135-2 in the PCB 1130 of the motor assembly 1100, where distances of the first moisture detection circuit 1135-1 and the second moisture detection circuit 1135-2 from the flow path are different from each other.

The at least one processor 1010 according to an embodiment of the disclosure may estimate the amount of moisture introduced into the cleaner body 1000 through the flow path by using the first moisture detection circuit 1135-1 and the second moisture detection circuit 1135-2. The at least one processor 1010 may stop driving of the suction motor 1110 when the estimated amount of moisture is equal to or greater than a reference amount.

The moisture detection circuit 1135 according to an embodiment of the disclosure may be provided on a top surface of the PCB 1130 or a bottom surface of the PCB 1130.

The at least one processor 1010 according to an embodiment of the disclosure may receive information about a moisture detection sensitivity set by a user from the server device 300. The at least one processor 1010 may change the reference voltage value based on the moisture detection sensitivity set by the user.

Values of resistors included in the moisture detection circuit 1135 according to an embodiment of the disclosure may be determined based on a predefined moisture detection sensitivity.

Mounting positions of the resistors included in the moisture detection circuit 1135 according to an embodiment of the disclosure in the PCB 1130 may be determined based on a predefined moisture detection sensitivity or a flow path structure (moisture ingress path) inside the cleaner body 1000, a shape (or structure) of a guard device (e.g., the cap grille 503) located on a front portion of the PCB 1130, a suction power strength, etc.

The at least one processor 1010 according to an embodiment of the disclosure may store, in the memory 1900, information indicating that driving of the suction motor 1110 has been stopped due to moisture ingress into the cleaner body 1000.

The vacuum cleaner according to an embodiment of the disclosure may further include an output interface configured to output a notification message indicating that moisture has been introduced into the cleaner body 1000.

The at least one processor 1010 according to an embodiment of the disclosure may determine whether moisture has been introduced into the cleaner body 1000 through the moisture detection circuit 1135 before driving of the suction motor 1110, in response to a user input that turns on the power of the vacuum cleaner. The at least one processor 1010 may deactivate driving of the suction motor 1110 when it is determined that moisture has been introduced into the cleaner body 1000. The at least one processor 1010 may control a display to display that driving of the suction motor 1110 has been deactivated.

The at least one processor 1010 according to an embodiment of the disclosure may compare a voltage value input through the moisture detection circuit 1135 before driving of the suction motor 1110 with a first reference voltage value. When the voltage value input through the moisture detection circuit 1135 is equal to or greater than the first reference voltage value, the at least one processor 1010 may compare the voltage value input through the moisture detection circuit 1135 with a second reference voltage value. When the voltage value input through the moisture detection circuit 1135 is equal to or greater than the second reference voltage value, the at least one processor 1010 may deactivate driving of the suction motor 1110.

When the voltage value input through the moisture detection circuit 1135 is equal to or greater than the first reference voltage value and less than the second reference voltage value, the at least one processor 1010 according to an embodiment of the disclosure may adjust the first reference voltage value.

When the voltage value input through the moisture detection circuit 1135 is less than the first reference voltage value, the at least one processor 1010 according to an embodiment of the disclosure may drive the suction motor 1110. When the voltage value input through the moisture detection circuit 1135 during driving of the suction motor 1110 is equal to or greater than a third reference voltage value, the at least one processor 1010 according to an embodiment of the disclosure may stop driving of the suction motor 1110.

When the at least one processor 1010 according to an embodiment of the disclosure detects moisture ingress into the cleaner body 1000 through the moisture detection circuit 1135 and an operation mode of the vacuum cleaner is in a maximum suction power mode, the at least one processor 1010 may determine whether the number of times moisture ingress is detected is equal to or greater than a predetermined number of times. When the number of times moisture ingress is detected is equal to or greater than the certain number of times, the at least one processor 1010 may stop driving of the suction motor 1110.

When moisture ingress into the cleaner body 1000 is detected through the moisture detection circuit 1135 and an operation mode of the vacuum cleaner is in a first suction power mode, the at least one processor 1010 according to an embodiment of the disclosure may change an operation mode to a second suction power mode with a suction power strength lower than that of the first suction power mode. When moisture ingress into the cleaner body 1000 is not detected through the moisture detection circuit 1135 in the second suction power mode, the at least one processor 1010 may maintain driving of the suction motor 1110. When moisture ingress into the cleaner body 1000 is detected through the moisture detection circuit 1135 in the second suction power mode, the at least one processor 1010 may stop driving of the suction motor 1110.

A machine-readable storage medium may be provided as a non-transitory storage medium. Here, ‘non-transitory’ means that the storage medium does not include a signal (e.g., an electromagnetic wave) and is tangible, but does not distinguish whether data is stored semi-permanently or temporarily in the storage medium. For example, the ‘non-transitory storage medium’ may include a buffer in which data is temporarily stored.

According to an embodiment of the disclosure, methods according to various embodiments of the disclosure may be provided in a computer program product. The computer program product is a product purchasable between a seller and a purchaser. The computer program product may be distributed in a form of machine-readable storage medium (e.g., a compact disc read-only memory (CD-ROM) or a universal serial bus (USB) flash drive), or distributed (e.g., downloaded or uploaded) through an application store or directly or online between two user devices (e.g., smartphones). When distributed online, at least part of the computer program product (e.g., a downloadable application) may be temporarily generated or at least temporarily stored in a machine-readable storage medium, such as a memory of a server of a manufacturer, a server of an application store, or a relay server.

What is claimed is:

1. A vacuum cleaner comprising:
a battery module configured to supply power to a cleaner body;
a motor assembly comprising a printed circuit board (PCB), a suction motor, and an impeller arranged in this order along a direction of a flow path in the cleaner body;
a moisture detection circuit provided on the PCB of the motor assembly and configured to detect moisture introduced thereinto through the flow path; and
at least one processor configured to stop driving of the suction motor when it is determined, through the moisture detection circuit, that moisture has been introduced into the cleaner body.

2. The vacuum cleaner of claim 1, wherein the moisture detection circuit is located between a positive (+) terminal and a negative (−) terminal of the PCB, which electrically connect the motor assembly to the battery module.

3. The vacuum cleaner of claim 1, wherein the moisture detection circuit is connected to an input port of a first processor of the motor assembly included in the PCB and a positive (+) power line which receives power from the battery module.

4. The vacuum cleaner of claim 1, wherein the at least one processor comprises at least one of a main processor of the cleaner body or a first processor of the motor assembly,
wherein the first processor of the motor assembly is configured to, when it is identified, through the moisture detection circuit, that moisture has been introduced into the cleaner body, transmit information indicating that moisture has been introduced into the cleaner body to the main processor, and receive, from the main processor, a signal indicating to stop driving of the suction motor.

5. The vacuum cleaner of claim 1, wherein the at least one processor is further configured to determine whether moisture has been introduced into the cleaner body by comparing a voltage value input through the moisture detection circuit with a reference voltage value.

6. The vacuum cleaner of claim 5, wherein the at least one processor is further configured to, when the voltage value input through the moisture detection circuit is equal to or greater than the reference voltage value, stop driving of the suction motor,
wherein the reference voltage value is predefined based on a resistance value corresponding to an electrical conductivity of urine of a pet.

7. The vacuum cleaner of claim 5, wherein the voltage value input to the at least one processor through the moisture detection circuit varies based on an electrical conductivity of moisture introduced into the cleaner body.

8. The vacuum cleaner of claim 1, wherein the moisture detection circuit comprises a first moisture detection circuit and a second moisture detection circuit located in the PCB of the motor assembly, wherein distances of the first moisture detection circuit and the second moisture detection circuit from the flow path are different from each other.

9. The vacuum cleaner of claim 8, wherein the at least one processor is further configured to
estimate an amount of moisture introduced into the cleaner body through the flow path, by using the first moisture detection circuit and the second moisture detection circuit, and
stop driving of the suction motor when the estimated amount of moisture is equal to or greater than a reference amount.

10. The vacuum cleaner of claim 1, wherein the moisture detection circuit is provided on a top surface of the PCB or a bottom surface of the PCB.

11. The vacuum cleaner of claim 5, wherein the at least one processor is further configured to
receive information about a moisture detection sensitivity set by a user from a server device, and
change the reference voltage value based on the moisture detection sensitivity set by the user.

12. The vacuum cleaner of claim 1, wherein values of resistors included in the moisture detection circuit are determined based on a predefined moisture detection sensitivity.

13. The vacuum cleaner of claim 1, wherein the at least one processor is further configured to store, in a memory, information indicating that driving of the suction motor has been stopped due to moisture ingress into the cleaner body.

14. The vacuum cleaner of claim 1, further comprising an output interface configured to output a notification message indicating that moisture has been introduced into the cleaner body.

15. The vacuum cleaner of claim 1, further comprising a display,
wherein the at least one processor is further configured to
determine, through the moisture detection circuit, whether moisture has been introduced into the cleaner body before driving of the suction motor, in response to a user input that turns on power of the vacuum cleaner,
deactivate driving of the suction motor when it is determined that moisture has been introduced into the cleaner body, and
control the display to display that driving of the suction motor has been deactivated.

16. The vacuum cleaner of claim 15, wherein the at least one processor is further configured to
compare a voltage value input through the moisture detection circuit before driving of the suction motor with a first reference voltage value,
when the voltage value input through the moisture detection circuit is equal to or greater than the first reference voltage value, compare the voltage value input through the moisture detection circuit with a second reference voltage value, and
when the voltage value input through the moisture detection circuit is equal to or greater than the second reference voltage value, deactivate driving of the suction motor.

17. The vacuum cleaner of claim 16, wherein the at least one processor is further configured to adjust the first reference voltage value when the voltage value input through the moisture detection circuit is equal to or greater than the first reference voltage value and less than the second reference voltage value.

18. The vacuum cleaner of claim 16, wherein the at least one processor is further configured to
drive the suction motor when the voltage value input through the moisture detection circuit is less than the first reference voltage value, and
stop driving of the suction motor, when the voltage value input through the moisture detection circuit during driving of the suction motor is equal to or greater than a third reference voltage value.

19. The vacuum cleaner of claim 1, wherein the at least one processor is further configured to,
when moisture ingress into the cleaner body is detected through the moisture detection circuit and an operation mode of the vacuum cleaner is in a maximum suction power mode, determine whether the number of times moisture ingress is detected is equal to or greater than a predetermined number of times, and
when the number of times moisture ingress is detected is equal to or greater than the predetermined number of times, stop driving of the suction motor.

20. The vacuum cleaner of claim 1, wherein the at least one processor is further configured to,
when moisture ingress into the cleaner body is detected through the moisture detection circuit and an operation mode of the vacuum cleaner is in a first suction power mode, change an operation mode to a second suction power mode with a suction power strength lower than a suction power strength of the first suction power mode,
when moisture ingress into the cleaner body is not detected through the moisture detection circuit in the second suction power mode, maintain driving of the suction motor, and
when moisture ingress into the cleaner body is detected through the moisture detection circuit in the second suction power mode, stop driving of the suction motor.
